(19) United States
(12) Patent Application Publication
(10) Pub. No.: US 2007/0068657 A1
(43) Pub. Date: Mar. 29, 2007

(54) Sheet -shaped heat pipe and method of manufacturing the same

(76) Inventors: Kenichi Yamamoto, Osaka (JP); Teruo Maruyama, Osaka (JP); Akio Mitsuhashi, Osaka (JP); Daisuke Suetsugu, Osaka (JP); Daido Komyoji, Nara (JP)

Correspondence Address: WENDEROTH, LIND & PONACK L.L.P., 2033 K. STREET, NW, SUITE 800, WASHINGTON, DC, 20006, US

(21) Appl. No.: 11/526,031

(22) Filed: Sep. 25, 2006

(30) Foreign Application Priority Data
Sep. 27, 2005 (JP) 2005 -279691
Sep. 27, 2005 (JP) 2005-279692
Nov. 29, 2005 (JP) 2005-343252

(51) Int. Cl. H05K 7/20

(52) U.S. Cl. 165/104.26; 165/104.33; 165/80.4; 361/700

(57) ABSTRACT

A sheet-shaped heat pipe including working fluid, a partition plate having a vapor flow path which is formed by a concave portion provided in a spacer and through which vapor of the working fluid passes and a fluid flow path provided on an inner surface of the concave portion through which the working fluid passes, a container with an opening portion, which includes the working fluid and the partition plate inside thereof, and a sealed portion for hermetically sealing the opening portion of the container. Since container has a laminated structure of at least a metal film and a resin film, it realizes a sheet-shaped heat pipe with high flexibility and little deterioration of a sealing performance.

### BACKGROUND OF THE INVENTION

1. Field of the Invention

The present invention relates to a sheet-shaped heat pipe for cooling a heat generating portion, which is used in electronic equipment such as an optical device, a notebook personal computer, and the like, and a method of manufacturing the sheet-shaped heat pipe.

2. Background Art

Recently, the development of electronic equipment such as information communication equipment has been remarkable. In particular, related equipment of a personal computer has higher performance and has been miniaturized. Since high performance has brought about the increase in an amount of generated heat and miniaturization has brought about the increase in a density of generated heat, solution for heat dissipation has come to be important.

For example, an optical disk device that is an information recording medium is required to offer large memory capacity and high-speed recording. When these requirements are to be achieved, an amount of heat generated from components constituting an optical pick-up portion, for example, a semiconductor laser, a high frequency circuit module, and a coil for driving, is increased. Therefore, in order to reduce the influence of heat on the semiconductor laser, the optical pick-up portion is required to be cooled. In an optical pick-up portion used in a conventional optical disk device, Japanese Patent Unexamined Publication No. 10-283650 (hereinafter, referred to as “patent document 1”) discloses a method of efficiently dissipating heat by coupling a first heat dissipating member and a second heat dissipating member which are provided on a heat generating component via a thermal conductive sheet. In this method, since the thermal conductive sheet uses a graphite sheet, it can cool the semiconductor laser without preventing the movement of the optical pick-up in the horizontal direction.

However, an optical pick-up portion moves in a wide range while it undergoes bending deformation frequently at the time of driving. Therefore, in order to transfer the heat generated in the optical pick-up portion to a heat dissipating portion of a main body, flexibility corresponding to small bending deformation as well as durability corresponding to highly frequent bending deformation are required.

Then, a means of efficiently dissipating heat in limited space employs a configuration in which heat generated from a heat generating portion is transferred to a heat dissipating portion provided in electronic equipment so as to dissipate the heat.

An example of a heat pipe corresponding to the above-mentioned purpose includes a sheet-shaped heat pipe shown in FIGS. 31A and 31B disclosed in Japanese Patent Unexamined Publication No. 2001-165584 (hereinafter, referred to as “patent document 2”).

FIG. 31A is a perspective plan view showing a conventional sheet-shaped heat pipe, and FIG. 31B is a sectional view taken along line 31B-31B of FIG. 31A.

As shown in FIGS. 31A and 31B, conventional sheet-shaped heat pipe 400 includes slender sheet-shaped container 404 made of films, which is formed by attaching outer peripheral ends 408 of two films 402 such as metal foils to each other with sealant layer 403, and working fluid (not shown) filled in container 404. Furthermore, a plurality of vapor flow paths 406 partitioned by a plurality of spacers 405 are formed, and fluid flow paths 407 for refluxing the working fluid by the capillary phenomenon are formed on the upper and lower surfaces of respective vapor flow paths 406.

Then, sheet-shaped heat pipe 400 is used in a way in which a vaporizing portion (not shown) at one end in the longitudinal direction is mounted on, for example, a heat generating portion of electronic equipment, and a condensing portion (not shown) at the other end is mounted on a heat dissipating portion of electronic equipment.

Furthermore, the operation of the sheet-shaped heat pipe is described. Firstly, working fluid inside the sheet-shaped heat pipe that is brought into contact with the heat generating portion of electronic equipment becomes vapor through evaporation by heat. Furthermore, this vapor passes through vapor flow path 406 in sheet-shaped heat pipe 400 and is transferred to the heat dissipating portion at the side of the condensing portion where the vapor is deprived of heat so as to be condensed and become working fluid again. Then, the working fluid is refluxed to the vaporizing portion through fluid flow path 407 of sheet-shaped heat pipe 400 by the capillary phenomenon.

That is to say, sheet-shaped heat pipe 400 repeats the above-mentioned operation so as to dissipate heat in electronic equipment from the heat dissipating portion for cooling.

In this way, in a conventional sheet-shaped heat pipe, since a container is formed of a sheet-shaped film, thinner thickness, light weight and flexibility are obtained. For example, the sheet-shaped heat pipe has been suitable for dissipating heat generated at a central processing unit of a notebook personal computer from a heat dissipating portion at the side of display via a hinge portion.

However, in the configuration shown in patent document 1, in order to increase the flexibility of a graphite sheet, thickness is required to be thin. In this case, on the contrary, heat transfer performance is reduced. Also when the length of the graphite sheet is increased, heat transfer performance is similarly reduced. Therefore, it is relatively difficult to increase the distance between a heat generating portion and a heat dissipating portion.

Furthermore, according to the sheet-shaped heat pipe shown in patent document 2, a sheet-shaped container is formed in a way in which two films such as metal foil are attached to each other with a sealant layer. Therefore, when the sheet-shaped heat pipe undergoes repetitive stress due to small bending deformation, peeling and crack occur in the bonding portion of the sealant layer located at the outer peripheral end on the central line of the bending deformation, thus deteriorating the sealing performance. Furthermore, there is neither description nor suggestion as to preventing the vapor flow path in the container from being clogged when the container is bent.

Then, when a sheet-shaped container is formed of resin material, working fluid is absorbed by a container in the state of liquid phase and vapor phase, and the working fluid permeates a container and is scattered to outside. Thereby, the container does not withstand the long term use.

### SUMMARY OF THE INVENTION

A sheet-shaped heat pipe of the present invention includes working fluid; a partition plate including a spacer having a fluid flow path through which the working fluid passes and a vapor flow path through which vapor of the working fluid passes; a container with an opening portion, including the working fluid and the partition plate inside thereof; and a sealed portion for hermetically sealing the opening portion of the container.

Furthermore, a method of manufacturing a sheet-shaped heat pipe of the present invention includes: forming a cylindrical container with an opening portion, in which at least a metal film and a resin film are laminated; encapsulating a partition plate having a vapor flow path and a fluid flow path in the container; infusing working fluid from the opening portion of the container; and forming a sealed portion by bonding the opening portion of the container.

Furthermore, a sheet-shaped heat pipe of the present invention includes a sheet-shaped container having flexibility; inside of which is maintained in a reduced pressure state; working fluid filled in the container, a vapor flow path and a fluid flow path of the working fluid, which are provided inside the container; and a plurality of supports provided inside the container for preventing the vapor flow path from being clogged.

Furthermore, a cooling structure for electronic equipment of the present invention includes electronic equipment having a heat generating portion, and a heat transfer means, which is brought into close contact with the heat generating portion, for transferring heat generated at the heat generating portion to a heat dissipating region. The heat transfer means is the above-mentioned sheet-shaped heat pipe and an electrode terminal of a conductive film is coupled to a ground terminal of the electronic equipment.

### BRIEF DESCRIPTION OF THE DRAWINGS

FIG. 1A is a perspective plan view showing a sheet-shaped heat pipe in accordance with a first embodiment of the present invention.

FIG. 1B is a sectional view taken along line 1B-1B of FIG. 1A.

FIG. 1C is a sectional view taken along line 1C-1C of FIG. 1A.

FIG. 2 is an enlarged perspective view of a principal part to illustrate a fluid flow path of the sheet-shaped heat pipe in accordance with the first embodiment of the present invention.

FIG. 3A is a process sectional view to illustrate a method of manufacturing an intermediate of the sheet-shaped heat pipe in accordance with the first embodiment of the present invention.

FIG. 3B is a process sectional view to illustrate a method of manufacturing an intermediate of the sheet-shaped heat pipe in accordance with the first embodiment of the present invention.

FIG. 3C is a process sectional view to illustrate a method of manufacturing an intermediate of the sheet-shaped heat pipe in accordance with the first embodiment of the present invention.

FIG. 3D is a process sectional view to illustrate a method of manufacturing an intermediate of the sheet-shaped heat pipe in accordance with the first embodiment of the present invention.

FIG. 4 is a sectional view to illustrate a method of infusing working fluid of the sheet-shaped heat pipe in accordance with the first embodiment of the present invention.

FIG. 5 is a perspective plan view to illustrate a method of manufacturing the sheet-shaped heat pipe in accordance with the first embodiment of the present invention.

FIG. 6A is a perspective plan view showing another example 1 of the sheet-shaped heat pipe in accordance with the first embodiment of the present invention.

FIG. 6B is a sectional view taken along line 6B-6B of FIG. 6A.

FIG. 6C is a sectional view taken along line 6C-6C of FIG. 6A.

FIG. 7A is a perspective plan view showing another example 2 of the sheet-shaped heat pipe in accordance with the first embodiment of the present invention.

FIG. 7B is a sectional view taken along line 7B-7B of FIG. 7A.

FIG. 7C is a sectional view taken along line 7C-7C of FIG. 7A.

FIG. 8A is a perspective plan view showing a sheet-shaped heat pipe in accordance with a second embodiment of the present invention.

FIG. 8B is a sectional view taken along line 8B-8B of FIG. 8A.

FIG. 8C is a sectional view taken along line 8C-8C of FIG. 8A.

FIG. 9A is a perspective plan view to illustrate another example of a container of the sheet-shaped heat pipe in accordance with the second embodiment of the present invention.

FIG. 9B is a sectional view taken along line 9B-9B of FIG. 9A.

FIG. 9C is a sectional view taken along line 9C-9C of FIG. 9A.

FIG. 10A is a sectional view to illustrate another example 1 of the sheet-shaped heat pipe in accordance with the second embodiment of the present invention.

FIG. 10B is a sectional view to illustrate another example 2 of the sheet-shaped heat pipe in accordance with the second embodiment of the present invention.

FIG. 11A is a perspective plan view showing a sheet-shaped heat pipe in accordance with a third embodiment of the present invention.

FIG. 11B is a sectional view taken along line 11B-11B of FIG. 11A.

FIG. 11C is an enlarged sectional view showing a principal part of FIG. 11B.

FIG. 11D is a sectional view taken along line 11D-11D of FIG. 11A.

FIG. 12A is a process sectional view to illustrate a method of manufacturing a sheet-shaped heat pipe in accordance with the third embodiment of the present invention.

FIG. 12B is a process sectional view to illustrate a method of manufacturing a sheet-shaped heat pipe in accordance with the third embodiment of the present invention.

FIG. 12C is a process sectional view to illustrate a method of manufacturing a sheet-shaped heat pipe in accordance with the third embodiment of the present invention.

FIG. 12D is a process sectional view to illustrate a method of manufacturing a sheet-shaped heat pipe in accordance with the third embodiment of the present invention.

FIG. 13 is a sectional view to illustrate another example of a method of manufacturing a participating plate of the sheet-shaped heat pipe in accordance with the third embodiment of the present invention.

FIG. 14A is a perspective plan view showing a sheet-shaped heat pipe in accordance with a fourth embodiment of the present invention.

FIG. 14B is a sectional view taken along line 14B-14B of FIG. 14A.

FIG. 14C is a sectional view taken along line 14C- 14C of FIG. 14A.

FIG. 15A is a perspective plan view to illustrate a method of manufacturing a container of the sheet-shaped heat pipe in accordance with the fourth embodiment of the present invention.

FIG. 15B is a sectional view taken along line 15B-15B of FIG. 15A.

FIG. 16 is a sectional view to illustrate a method of infusing working fluid of the sheet-shaped heat pipe in accordance with the forth embodiment of the present invention.

FIG. 17 is a perspective plan view to illustrate a method of manufacturing a sheet-shaped container of the sheet-shaped heat pipe in accordance with the fourth embodiment of the present invention.

FIG. 18A is a sectional view to illustrate a method of forming a metal film of a sealing layer of the sheet-shaped heat pipe in accordance with the fourth embodiment of the present invention.

FIG. 18B is a sectional view to illustrate a method of forming a resin film of a sealing layer of the sheet-shaped heat pipe in accordance with the fourth embodiment of the present invention.

FIG. 19A is a perspective plan view showing a sheet-shaped heat pipe in accordance with a fifth embodiment of the present invention.

FIG. 19B is a sectional view taken along line 19B-19B of FIG. 19A.

FIG. 19C is a sectional view taken along line 19C-19C of FIG. 19A.

FIG. 20 is a sectional view to illustrate another example of a sealing layer of the sheet-shaped heat pipe in accordance with the fifth embodiment of the present invention.

FIG. 21A is a sectional view showing another example 1 of the sheet-shaped heat pipe in accordance with the fifth embodiment of the present invention.

FIG. 21B is a sectional view showing another example 2 of the sheet-shaped heat pipe in accordance with the fifth embodiment of the present invention.

FIG. 21C is a sectional view showing another example 3 of the sheet-shaped heat pipe in accordance with the fifth embodiment of the present invention.

FIG. 22 is a view to illustrate a state in which a sheet-shaped heat pipe is mounted on electronic equipment in accordance with a sixth embodiment of the present invention.

FIG. 23A is a plan view showing a sheet-shaped heat pipe in accordance with a seventh embodiment of the present invention.

FIG. 23B is a sectional view taken along line 23B-23B of FIG. 23A.

FIG. 24A is a schematic view showing an outline to illustrate a configuration for cooling a heat generation portion of electronic equipment by using the sheet-shaped heat pipe in accordance with the seventh embodiment of the present invention.

FIG. 24B is a schematic view showing an outline to illustrate a configuration for cooling a heat generation portion of electronic equipment by using the sheet-shaped heat pipe in accordance with the seventh embodiment of the present invention.

FIG. 25 is a sectional view of the short-side direction of another example 1 of the sheet-shaped heat pipe in accordance with the seventh embodiment of the present invention.

FIG. 26A is a plan view showing a lower sheet of a sheet-shaped container constituting another example 1 of the sheet-shaped heat pipe in accordance with the seventh embodiment of the present invention.

FIG. 26B is a sectional view taken along line 26B-26B of FIG. 26A.

FIG. 26C is a plan view showing another example 1 of an upper sheet of a sheet-shaped container constituting the sheet-shaped heat pipe in accordance with the seventh embodiment of the present invention.

FIG. 26D is a sectional view taken along line 26D-26D of FIG. 26C.

FIG. 27 is a plan view to illustrate a configuration of another example 2 of the sheet-shaped heat pipe in accordance with the seventh embodiment of the present invention.

FIG. 28 is a plan view showing a configuration of a sheet-shaped heat pipe in accordance with an eighth embodiment of the present invention.

FIG. 29 is a sectional view to illustrate a configuration of cooling a heat generation portion mounted on a surface of a circuit board built in electronic equipment in accordance with the eighth embodiment of the present invention.

FIG. 30 is a sectional view showing a configuration of a cooling structure of electronic equipment configured by using a modified example of the sheet-shaped pipe in accordance with the eighth embodiment of the present invention.

FIG. 31A is a perspective plan view showing a conventional sheet-shaped heat pipe.

FIG. 31B is a sectional view taken along line A-A of FIG. 31A.

### DETAILED DESCRIPTION OF THE INVENTION

Hereinafter, embodiments of the present invention are described with reference to drawings.

### First Embodiment

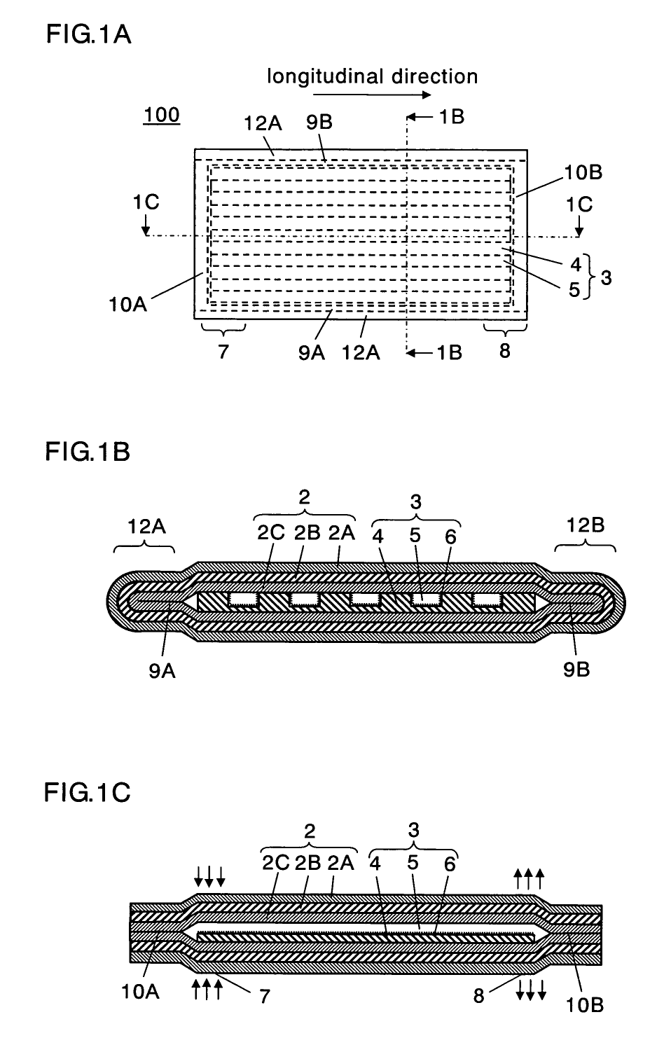

FIG. 1A is a perspective plan view showing a sheet-shaped heat pipe in accordance with a first embodiment of the present invention, FIG. 1B is a sectional view taken along line 1B-1B of FIG. 1A, and FIG. 1C is a sectional view taken along line 1C-1C of FIG. 1A.

In FIGS. 1A to 1C, sheet-shaped heat pipe 100 in accordance with the first embodiment of the present invention includes container 2 made of a cylindrical sealing film and having sealed portions 10A and 10B for bonding the opening portions, and sheet-shaped partition plate (hereinafter, referred to as “partition plate) 3 encapsulated together with working fluid (not shown) whose saturated vapor pressure is low in container 2.

As shown in FIG. 1B, sheet-shaped partition plate 3 include a plurality of vapor flow paths 5 formed by a concave portion of spacer 4 along the longitudinal direction of the sheet-shaped heat pipe (see FIG. 1A), and fluid flow paths 6 each of which is provided on the inner surface of the concave portion of vapor flow path 5.

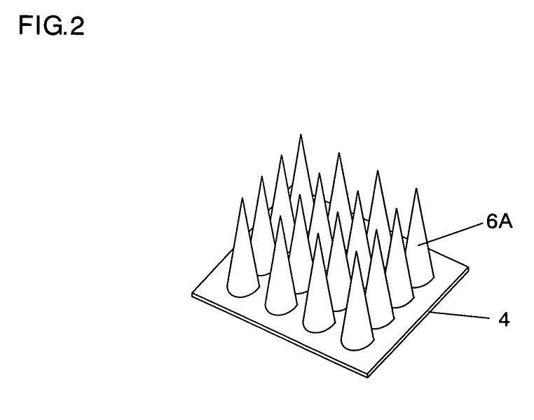

Herein, as shown in an enlarged perspective view of a principal part of fluid flow path 6 in FIG. 2, as fluid flow path 6, minute protrusions 6A are formed on the inner peripheral surface of vapor flow path 5 of spacer 4 made of, for example, aluminum, polyimide, and the like. Protrusion 6A is formed to, for example, 100 μm or less by surface treatment such as dry etching using plasma of oxygen, carbon tetrafluoride, and the like, or wet etching using phosphoric acid and the like. With protrusions 6A, the working fluid is refluxed to a vaporizing portion by the capillary phenomenon.

Furthermore, container 2 has a laminated structure including metal film 2B of, for example, aluminum and resin films 2A and 2C of, for example, polyimide.

Note here that by deforming container 2 made of a cylindrical sealing film into a sheet shape as shown in FIG. 1B, container 2 is adhesively bonded via bonding portions 9A and 9B of resin film 2C at the outside of the outer periphery in the longitudinal direction of partition plate 3, and at the same time, folding portions 12A and 12B without having a bonding portion are formed. On the other hand, as shown in FIG. 1C, the opening portions of container 2 are bonded in a way in which resin films 2C are fused to each other by, for example, heat, ultrasonic wave, and the like. Consequently, sealed portions 10A and 10B are formed. In this case, it is preferable that the length of sealed portions 10A and 10B of container 2 is as long as possible in the longitudinal direction. This configuration can reduce scattering of the working fluid to the outside via resin film 2C of sealed portions 10A and 10B.

Thus, as shown in FIG. 1C, for example, one end of sheet-shaped heat pipe 100 functions as vaporizing portion 7 of the working fluid and the other end functions as condensing portion 8 of the working fluid.

Herein, as resin films 2A and 2C of container 2, in addition to polyimide, a resin material such as polyethylene terephthalate is used. As metal film 2B of container 2, in addition to aluminum, a metallic material having flexibility, for example, copper is used. As the working fluid, ethanol, water, flon gas, and the like, which have low saturated vapor pressure, are used.

Furthermore, as spacer 4 of partition plate 3, a metallic material having flexibility, for example, aluminum and copper, or a resin material such as polyimide and polyethylene terephthalate can be used. Thus, partition plate 3 that is extremely flexible can be obtained.

Note here that vapor flow path 5 may have any depth that is not smaller than the height of protrusion 6A and it is designed in accordance with the desired cooling performance. For example, when the height of protrusion 6A is 100 μm, the depth of vapor flow path 5 may be 100 μm or more.

According to the first embodiment of the present invention, container 2 made of a cylindrical sealing film having a laminated structure is used, and container 2 can be sealed without having a sealed portion in the longitudinal direction. Thus, a sheet-shaped heat pipe having an excellent sealing property can be obtained.

In general, in the sheet-shaped heat pipe, the length in the longitudinal direction is relatively longer as compared with the width of the sealed portion and, a probability that the sealing performance is deteriorated is extremely high. However, according to the first embodiment of the present invention, since the bonding interface of the sealed portion is not exposed in the longitudinal direction, the probability that the sealing performance is deteriorated can be significantly reduced.

Furthermore, even when sheet-shaped heat pipe 100 is used in a place, for example, in an optical pick-up portion of an optical disk device, which moves in a wide range while undergoing bending deformation, since no bonding interface exposed to the outside of the sealed portion is present in the place undergoing bending deformation in the longitudinal direction, sheet-shaped heat pipe 100 is free from deterioration of sealing performance or deterioration of durability due to peeling, and the like. Thus, high reliability can be realized.

Resin films 2A and 2C of container 2 may be formed of thermosetting resin. Thus, flexibility and heat resistance of sheet-shaped heat pipe 100 are improved, so that deterioration of the sealing performance of container 2 due to softening and thermal deformation does not occur. Therefore, sheet-shaped heat pipe 100 can be used in, for example, a portion in which the change in temperature of electronic equipment is large or a high temperature portion.

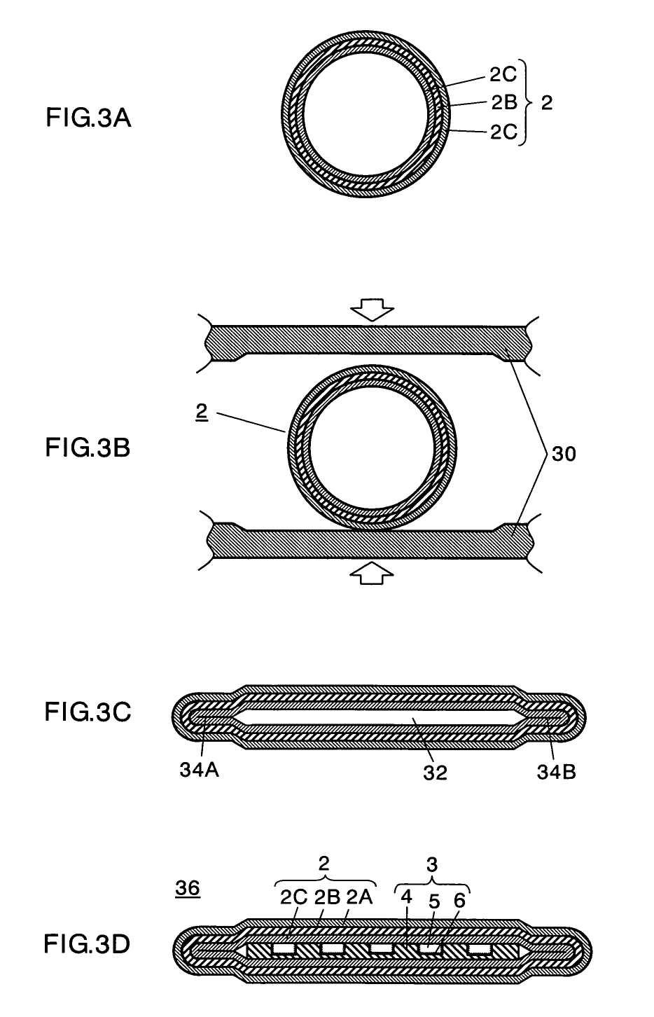

Hereinafter, a method of manufacturing a sheet-shaped heat pipe in accordance with the first embodiment of the present invention is described in detail with reference to FIG. 3A to FIG. 5.

FIGS. 3A to 3D are process sectional views to illustrate a method of manufacturing an intermediate of the sheet-shaped heat pipe in accordance with the first embodiment of the present invention.

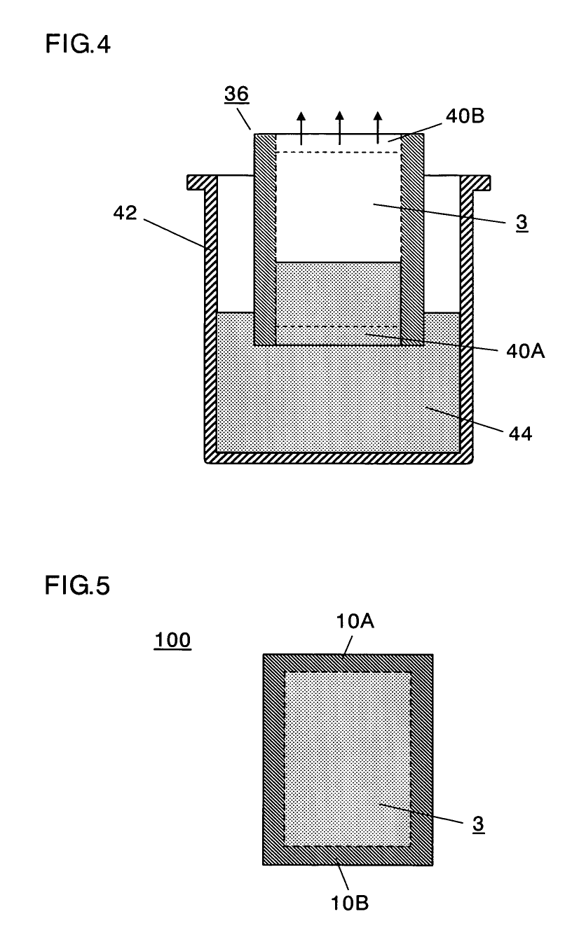

FIG. 4 is a sectional view to illustrate a method of infusing working fluid of the sheet-shaped heat pipe in accordance with the first embodiment of the present invention.

FIG. 5 is a perspective plan view to illustrate a method of manufacturing the sheet-shaped heat pipe in accordance with the first embodiment of the present invention.

Firstly, as shown in FIG. 3A, on the entire outer surface of cylindrical resin film 2C made of a resin material such as polyimide, metal film 2B made of a metallic material such as aluminum is formed to the thickness of about 1 μm to 10 μm by, for example, vapor deposition and plating. Furthermore, on at least the entire outer surface of metal film 2B, a resin material such as polyimide is formed to the thickness of, for example, several μm by for example, a spray method or a dipping method. Thus, container 2 made of a cylindrical sealing film is formed.

Note here that by dipping cylindrical metal film 2B into, for example, liquid polyimide, resin films 2A and 2C may be formed on both surfaces of cylindrical metal film 2B simultaneously. Needless to say, on the entire inner surface of resin film 2A, metal film 2B and resin film 2C may be formed.

Next, as shown in FIG. 3B, container 2 is put on press die 30 and pressed and heated from the direction of arrow so as to process container 2 into a predetermined shape.

Next, as shown in FIG. 3C, space 32 containing a partition plate mentioned below is formed and bonding portions 34A and 34B are formed by fusing resin films 2C to each other at both sides in the longitudinal direction of space 32.

Next, as shown in FIG. 3D, by inserting partition plate 3 including spacer 4 having vapor flow path 6 and fluid flow path 6 into the above-mentioned space 32, an intermediate of the sheet-shaped heat pipe (hereinafter, referred to as “intermediate”) 36 having opening portions (not shown) on both ends of the container is formed.

Herein, partition plate 3 is produced by the following method. Firstly, in, for example, polyethylene terephthalate resin as a spacer, a concave portion that functions as a vapor flow path is formed by die molding. Thereafter, a plurality of protrusions are formed by, for example, etching at least the inner surface of the concave portion. Consequently, the vapor flow paths and the fluid flow paths are integrally formed in the spacer, and thus a partition plate is produced.

Next, as shown in FIG. 4, one opening portion 40A of opening portions 40A and 40B of intermediate 36 is dipped into working fluid 44 such as ethanol contained in vessel 42 so that working fluid 44 is infused into the fluid flow path of partition plate 3. In this case, working fluid 44 is infused into the fluid flow path by the capillary phenomenon. In this case, for example, working fluid 44 may be infused in a state in which the pressure of the other opening portion 40B is reduced. Thus, working fluid 44 can be infused into the fluid flow path for a short time.

Next, as shown in FIG. 5, the opening portions of intermediate 36 are bonded by fusing by, for example, heat, ultrasonic wave, and the like, so that sealed portions 10A and 10B are formed.

Then, by the above-mentioned process, sheet-shaped heat pipe 100 encapsulating working fluid and a partition plate in a container and hermetically sealing at sealed portions is produced.

Note here that sheet-shaped heat pipe 100 may be produced from intermediate 36 by allowing working fluid to be sucked and infused into the fluid flow path of the partition plate in a reduced pressure atmosphere and by bonding opening portions 40A and 40B.

According to the manufacturing method in accordance with the first embodiment of the present invention, with a container made of a cylindrical sealing film, a sheet-shaped heat pipe having excellent sealing performance such as hermetic sealing can be manufactured efficiently and stably with a simple configuration.

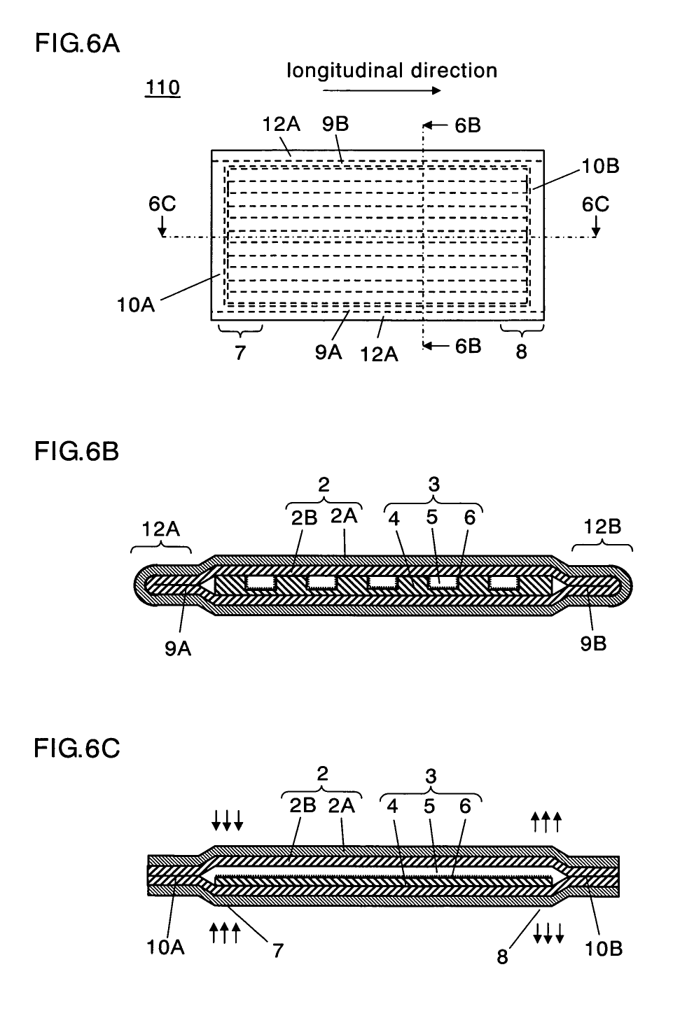

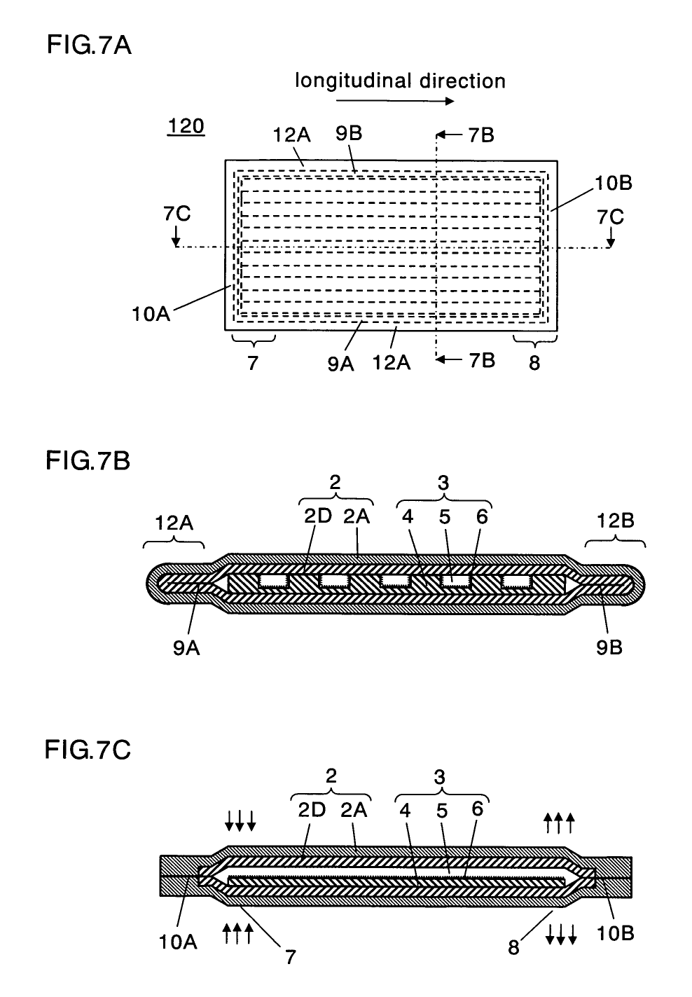

Hereinafter, another example of the sheet-shaped heat pipe in accordance with the first embodiment is described with reference to FIGS. 6A and 7B.

FIG. 6A is a perspective plan view showing another example 1 of the sheet-shaped heat pipe in accordance with the first embodiment of the present invention. FIG. 6B is a sectional view taken along line 6B-6B of FIG. 6A. FIG. 6C is a sectional view taken along line 6C-6C of FIG. 6A.

FIG. 7A is a perspective plan view showing another example 2 of the sheet-shaped heat pipe in accordance with the first embodiment of the present invention. FIG. 7B is a sectional view taken along line 7B-7B of FIG. 7A. FIG. 7C is a sectional view taken along line 7C-7C of FIG. 7A.

The above-mentioned other examples are different from the first embodiment in the structure of the container including a laminate structure of a metal film and a resin film.

Firstly, as shown in FIG. 6A to FIG. 6C, in sheet-shaped heat pipe 110 in accordance with another example 1, container 2 is formed in a two-layered laminated structure of resin film 2A and metal film 2B, and metal film 2B is provided at the side of partition plate 3.

Thus, absorption and permeation of working fluid by resin film 2A can be completely prevented by metal film 2B provided at the side of partition plate 3. Consequently, it is possible to realize a sheet-shaped heat pipe with high reliability in which less working fluid is absorbed and permeated and a cooling property is not easily deteriorated.

Furthermore, it is possible to realize a sheet-shaped heat pipe, which becomes thinner and therefore has high flexibility and excellent thermal conductivity with respect to a heat generating portion, a heat dissipating portion, and the like.

In this case, as shown in FIG. 6C, since opening portions of container 2 are fused by metal film 2B to form sealed portions 10A and 10B, it is more difficult to secure complete sealing performance as compared with the fusion of resin film 2A. This is because the melting temperature is generally high at the time of fusion of metal film 2B, bubbles easily occur in resin film 2A when metal film 2B is fused. Therefore, in sheet-shaped heat pipe 110 in accordance with another example 1, as mentioned in the following second embodiment of the present invention, it is preferable that a sealing layer is provided on sealed portions 10A and 10B so as to hermetically seal the bonding interfaces of the sealed portions of container 2.

Then, as shown in FIG. 7A and FIG. 7B, in sheet-shaped heat pipe 120 in accordance with another example 2, as compared with another example 1, in container 2, metal film 2D is formed at the side of partition plate 3 in a way in which film 2D is smaller (shorter) than resin film 2A in the longitudinal direction.

Thus, since sealing of sealed portions 10A and 10B of container 2 is carried out mainly by fusion of resin film 2A, fusion is carried out at low temperature and fusion interfaces of resin film 2A are integrated. Consequently, bonding that is excellent in sealing performance can be realized.

Therefore, in particular, in this case, as mentioned in the following second embodiment of the present invention, the sealing layer may be formed of only a resin film. However, needless to say, the sealing layer may be formed in a laminated configuration of a metal film and a resin film.

### Second Embodiment

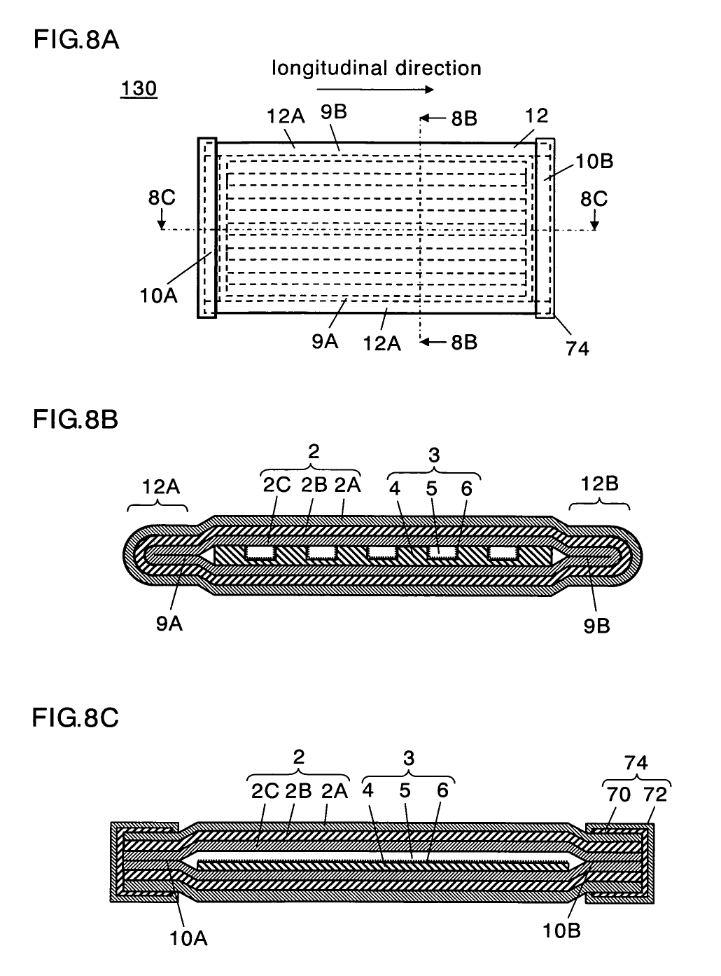

Hereinafter, a sheet-shaped heat pipe in accordance with a second embodiment of the present invention is described with reference to FIGS. 8A to 8C.

FIG. 8A is a perspective plan view showing sheet-shaped heat pipe 130 in accordance with the second embodiment of the present invention. FIG. 8B is a sectional view taken along line 8B-8B of FIG. 8A. FIG. 8C is a sectional view taken along line 8C-8C of FIG. 8A. In FIGS. 8A to 8C, the same reference numerals are given to the same configurations as in FIG. 1A to 1C and description therefor is omitted.

Sheet-shaped heat pipe 130 in accordance with the second embodiment of the present invention is different from the sheet-shaped pipe in accordance with the first embodiment in that sealing layers 74 for covering sealed portions 10A and 10B of sealing film 2 are provided.

In FIGS. 8A to 8C, sheet-shaped heat pipe 130 in accordance with the second embodiment of the present invention includes cylindrical container 2 having sealed portions 10A and 10B for bonding the opening portions, and sheet-shaped partition plate 3 encapsulated together with working fluid (not shown) whose saturated vapor pressure is low in container 2.

As shown in FIG. 8B, sheet-shaped partition plate 3 includes spacer 4 in which a plurality of vapor flow paths 5 are provided along the longitudinal direction of the sheet-shaped heat pipe (see FIG. 8A) and fluid flow paths 6 integrally provided on the inner surfaces of respective vapor flow paths 5.

Furthermore, container 2 has a laminated structure of metal film 2B such as aluminum and resin films 2A and 2C such as polyimide.

Note here that by deforming container 2 made of a cylindrical sealing film into a sheet shape as shown in FIG. 8B, container 2 is adhesively bonded via bonding portions 9A and 9B of resin film 2C at the outside of the outer periphery in the longitudinal direction of partition plate 3, and at the same time, folding portions 12A and 12B without having a bonding portion are formed.

On the other hand, as shown in FIG. 8C, the opening portions of container 2 made of a cylindrical sealing film are bonded in a way in which resin films 2C are fused by, for example, heat, ultrasonic wave, and the like, and sealed portions 10A and 10B are formed.

Furthermore, as shown in FIG. 8C, on sealed portions 10A and 10B of container 2, sealing layers 74 for covering at least exposed ends of sealed portions 10A and 10B are formed. Herein, sealing layer 74 has a laminated configuration of metal film 70 such as aluminum and resin film 72 such as polyimide.

Metal film 70 of sealing layer 74 can be formed by, for example, vapor deposition or plating. Furthermore, resin film 72 of sealing layer 74 can be formed by dipping into, for example, liquid polyimide.

As resin film 72 of sealing layer 74, in addition to polyimide, a resin material such as polyethylene terephthalate may be used. As metal film 70 of sealing layer 74, in addition to aluminum, a metallic material such as copper may be used.

According to the second embodiment of the present invention, since a sealing layer having a laminated structure can completely seal the exposed end face of the sealed portion, a sheet-shaped heat pipe that is further excellent in the sealing performance without deteriorating the flexibility can be obtained.

Furthermore, since the sealing layer covers the end face of the sealed portion, it is not necessary that the length in the longitudinal direction of the sealed portion is increased so as to prevent working fluid from permeating from the sealed portion. Therefore, a sheet-shaped heat pipe having a short sealed portion can be obtained.

Furthermore, with the sealing layer, since the thickness in the longitudinal direction of a sheet-shaped heat pipe can be made substantially uniform, the sheet-shaped heat pipe can be uniformly brought into contact with a heat generating portion or a heat dissipating portion easily. Thus, thermal conductivity can be improved.

Note here that similar to resin films 2A and 2C of the container, resin film 72 of sealing layer 74 may be formed of thermosetting resin. Thus, since the heat resistance of sheet-shaped heat pipe 130 is improved, deterioration of the sealing performance due to softening or thermal deformation of sealing layer 74 does not occur. Consequently, sheet-shaped heat pipe 130 can be used in, for example, a portion in which the temperature change is large or a high temperature portion in electronic equipment.

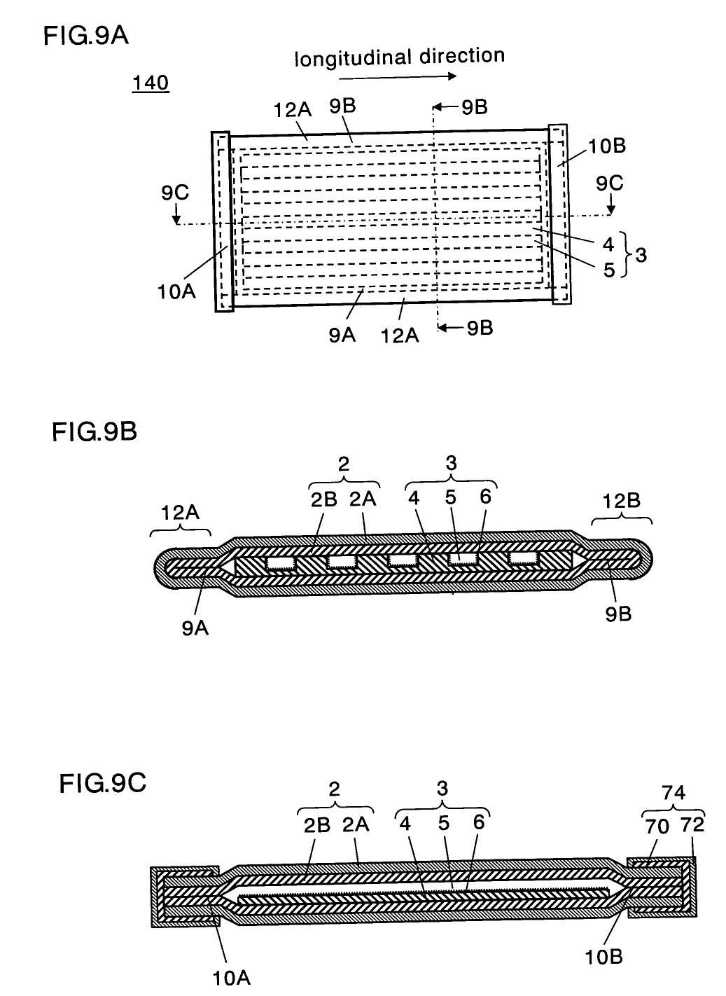

In the description of the second embodiment mentioned above, container 2 has a three-layered laminated structure of resin films 2A and 2C and metal film 2B. However, the structure is not necessarily limited to this. For example, as shown in another example of the container in accordance with the second embodiment in FIG. 9A to FIG. 9C, a container may be configured in a two-layered laminated structure of resin film 2A and metal film 2B in which metal film 2B is provided at the side of partition plate 3. Thus, it is possible to produce sheet-shaped heat pipe 140 that is thinner, is excellent in heat transfer efficiency, and has a cooling property that is not easily deteriorated because less working fluid is absorbed and permeated.

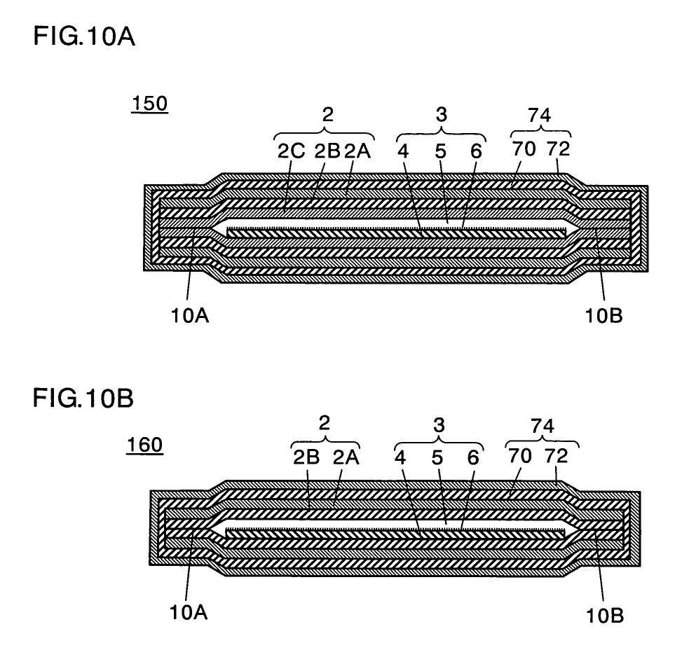

Hereinafter, another example of the sheet-shaped heat pipe in accordance with the second embodiment of the present invention is described with reference to FIGS. 10A and 10B.

As shown in FIG. 10A, in sheet-shaped heat pipe 150 in accordance with another example 1 of the second embodiment, on the entire outer surface of container 2 having a three-layered structure, sealing layer 74 made of, for example, metal film 70 and resin film 72 is formed.

Furthermore, as shown in FIG. 10B, in sheet-shaped heat pipe 160 in accordance with another example 2 of the second embodiment, on the entire outer surface of container 2 having a two-layered structure, sealing layer 74 made of, for example, metal film 70 and resin film 72 is formed.

Thus, the sealing performance of sheet-shaped heat pipes 150 and 160 can be further improved.

Furthermore, since a sealing layer is formed on the entire outer surface of the container, as compared with the case where the sealing layer is partially formed, the sealing layer is easily formed. Therefore, a sheet-shaped heat pipe can be produced with high productivity.

### Third Embodiment

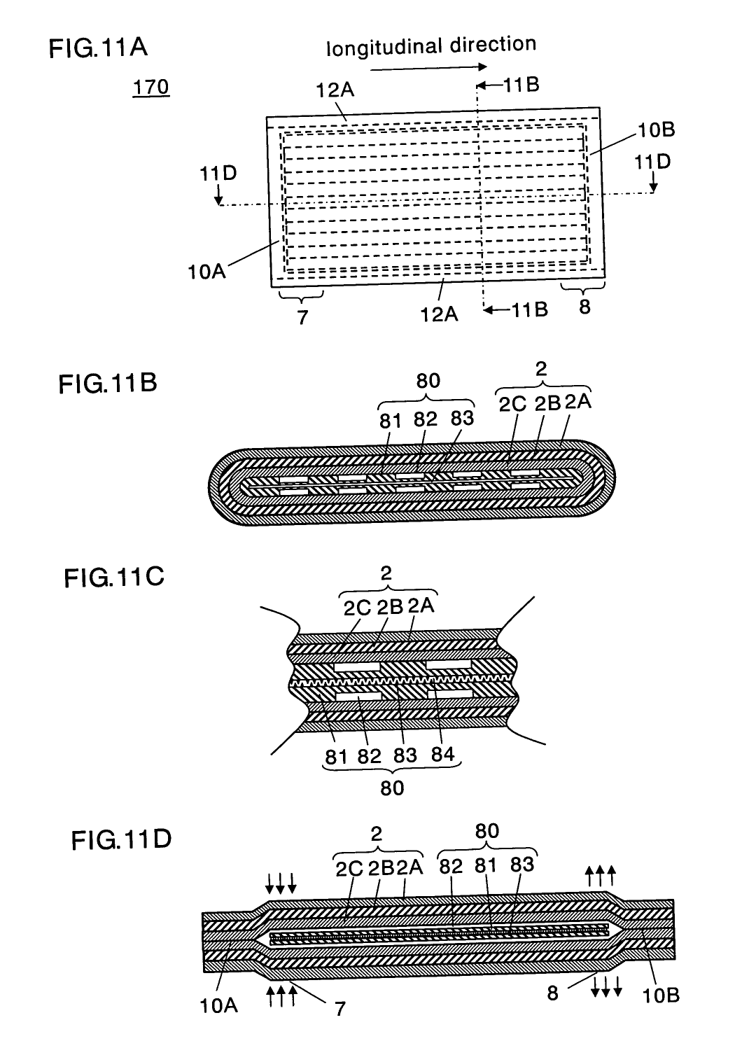

Hereinafter, a sheet-shaped heat pipe in accordance with a third embodiment of the present invention is described with reference to FIGS. 11A to 11D.

FIG. 11A is a perspective plan view showing sheet-shaped heat pipe 170 in accordance with the third embodiment of the present invention. FIG. 11B is a sectional view taken along line 11B-11B of FIG. 11A. FIG. 11C is an enlarged sectional view showing a principal part of FIG. 11B. FIG. 11D is a sectional view taken along line 11D-11D of FIG. 11A. In FIGS. 11A to 11D, the same reference numerals are given to the same configurations as in FIG. 1A to 1C and description therefor is omitted.

Sheet-shaped heat pipe 170 in accordance with the third embodiment of the present invention is different from that of the first embodiment in the configuration of partition plate 80.

That is to say, as shown in FIG. 11B, partition plate 80 has a configuration in which cylindrical spacer 81 is deformed into a sheet shape and the inner peripheral surfaces of spacer 81 are brought into contact with each other.

Then, vapor flow paths 82 are provided in the longitudinal direction at, for example, the outer peripheral side of spacer 81 and a rough surface corresponding to, for example, protrusions 83 as shown FIG. 2, is formed at the inner peripheral side of the spacer 81. The rough surface is formed by, for example, etching, sandblasting, and the like. As shown in FIG. 11C, clearance that is brought into contact with rough surface at the inner peripheral side of partition plate 80 makes fluid flow path 84.

Thus, since partition plate 80 has wide vapor flow path 82 and fluid flow path 84, sheet-shaped heat pipe 170 having an excellent cooling property can be obtained.

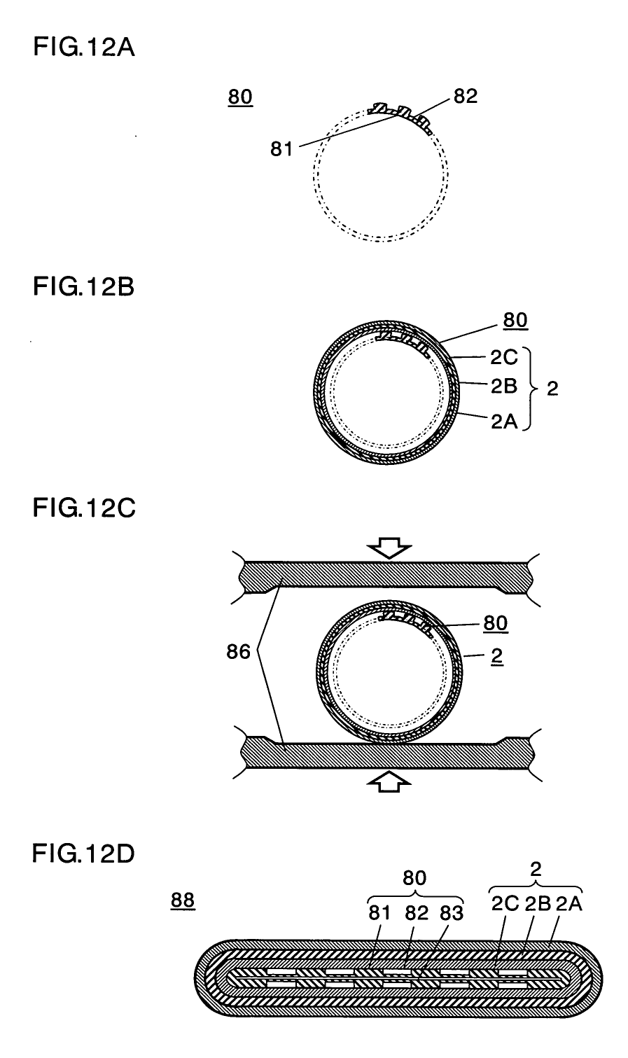

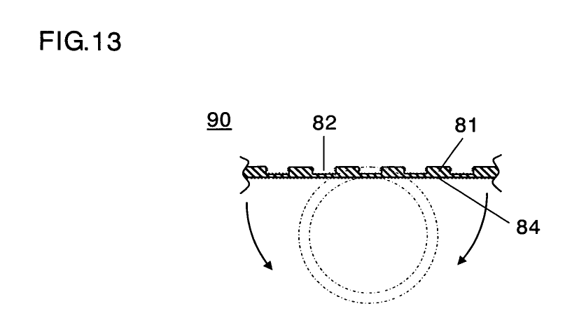

Hereinafter, a method of manufacturing sheet-shaped heat pipe 170 in accordance with the third embodiment of the present invention is described in detail with reference to FIGS. 12A to 12D.

FIGS. 12A to 12D are process sectional views to illustrate a method of manufacturing the sheet-shaped heat pipe in accordance with the third embodiment of the present invention.

Firstly, as shown in FIG. 12A, in cylindrical spacer 81 having flexibility and made of resin material, which is brought into contact with the inside of, for example, a cylindrical container, at the side of the outer peripheral surface, vapor flow paths 82 are provided along the longitudinal direction, and at the side of the inner peripheral surface, the surface is roughened, for example, protrusions and the like are provided. Thus, cylindrical partition plate 80 is produced. Herein, a concave portion that is vapor flow path 82 of spacer 81 can be formed in an arbitrary shape and depth by, for example, die molding, etching, and the like. Furthermore, protrusions and the like can be formed by the same method as mentioned in the first embodiment.

Next, as shown in FIG. 12B, cylindrical partition plate 80 is fitted into the inside of container 2 made of a cylindrical sealing film formed by the same method as mentioned in the second embodiment of the present invention.

Herein, container 2 has a three-layered structure of metal film 2B and resin films 2A and 2C. Partition plate 80 is brought into contact with resin film 2C.

Next, as show in FIG. 12C, container 2 into which cylindrical partition plate 80 is fitted is put on press die 86 and pressed and heated from the direction shown by arrows so as to be processed in a predetermined sheet-shaped shape.

Thus, as shown in FIG. 12D, intermediate 88 of a sheet-shaped heat pipe having opening portions (not shown) on both ends of container 2 into which cylindrical partition plate 80 is fitted is formed.

Next, as described in the first embodiment of the present invention with reference to FIG. 4, by dipping one of the opening portions of intermediate 88 into working fluid such as ethanol contained in a vessel, the working fluid infused into fluid flow path 84 of cylindrical partition plate 80. In this case, the working fluid may be infused into the fluid flow path by using the capillary phenomenon. For example, the working fluid may be infused into the fluid flow path in a state in which the pressure of the other opening portion is reduced. Thus, the working fluid can be infused for a short time.

Next, as shown in FIG. 11D, the opening portions of intermediate 88 are bonded by fusing by, for example, heat, ultrasonic wave, and the like, so that sealed portions 10A and 10B are formed.

Then, the above-mentioned process produces sheet-shaped heat pipe 170, in which container 2 encapsulates the working fluid and partition plate 80 and is hermetically sealed by sealed portions 10A and 10B.

Note here that sheet-shaped heat pipe 170 may be produced from intermediate 88 by allowing working fluid to be sucked and infused into fluid flow path 84 of partition plate 80 in a reduced-pressure atmosphere and by bonding the opening portions.

According to the manufacturing method in accordance with the third embodiment of the present invention, with a container made of a cylindrical sealing film, a sheet-shaped heat pipe having excellent sealing performance such as hermetic sealing can be manufactured efficiently and stably with a simple configuration.

Furthermore, since wide vapor flow paths and fluid flow paths are formed by a cylindrical partition plate, a sheet-shaped heat pipe having an excellent heat dissipation property can be obtained.

In the third embodiment of the present invention, a cylindrical partition plate is described as an example. The present invention is not necessarily limited to this. As shown in FIG. 13, sheet-shaped partition plate 90 including flat spacer 81 may be produced. In partition plate 90, vapor flow paths 82 are formed on one surface and fluid flow paths 84 made of protrusions formed by roughening the surface on the other surface. As shown by the alternate long and short dash line in FIG. 13, sheet-shaped partition plate 80 is rolled cylindrically and then fitted in a container, so that a sheet-shaped heat pipe can be formed. Note here that vapor flow paths and fluid flow paths can be formed by the same method as described in the above-mentioned embodiments.

According to this manufacturing method, since fluid flow paths and vapor flow paths can be formed on a flat spacer, a partition plate that is excellent in the shape and the positional precision can be manufactured simply with high productivity.

### Fourth Embodiment

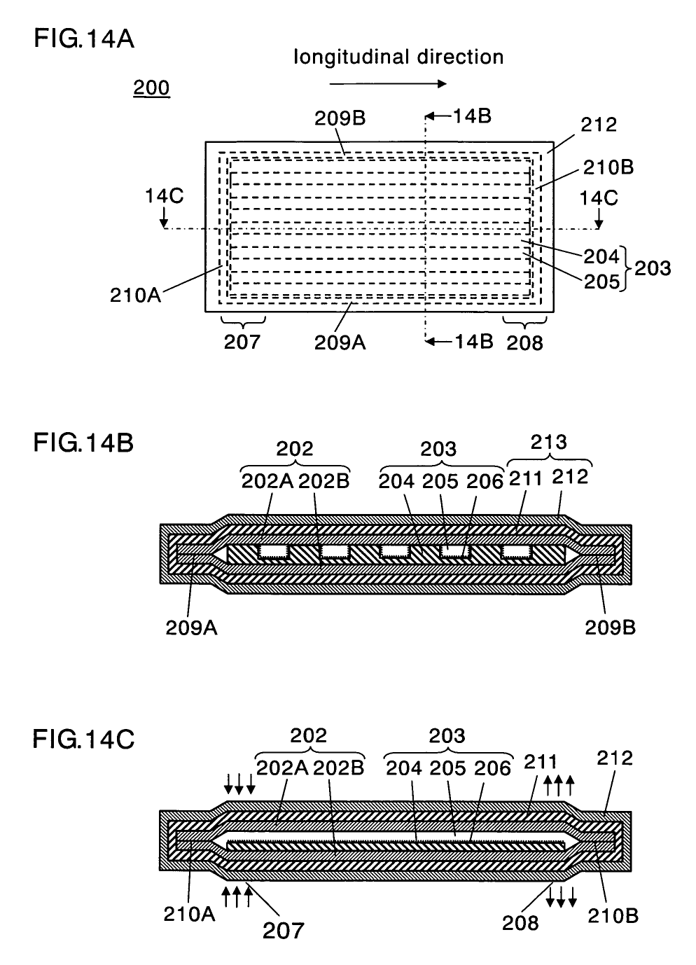

FIG. 14A is a perspective plan view showing a sheet-shaped heat pipe in accordance with a fourth embodiment of the present invention. FIG. 14B is a sectional view taken along line 14B-14B of FIG. 14A. FIG. 14C is a sectional view taken along line 14C-14C of FIG. 14A.

In FIGS. 14A to 14C, sheet-shaped heat pipe 200 in accordance with the fourth embodiment of the present invention includes sheet-shaped container 202 made of two flexible sealing sheets 202A and 202B which are bonded at the outer peripheries thereof, and sheet-shaped partition plate 203 made of flexible material encapsulated together with working fluid (not shown) whose saturated vapor pressure is low in container 202. Note here that the number of the sealing sheets is not particularly determined as long as it is two or more. In accordance with desired hermetic sealing property and flexibility, a plurality of sheets may be used.

Furthermore, as shown in FIG. 14B, as in the first embodiment, partition plate 203 has spacer 204 including a plurality of vapor flow paths 205 along the longitudinal direction of the sheet-shaped heat pipe (see FIG. 14A) and fluid flow paths 206 provided on the inner peripheral surfaces of respective vapor flow paths 205.

Herein, as shown in an enlarged perspective view of a principal part of the fluid flow path in FIG. 2, as in the first embodiment, as fluid flow path 206, minute protrusions 6A are formed on the inner peripheral surface of vapor flow path 205 of spacer 204 made of, for example, aluminum, polyimide, and the like. Protrusion 6A is formed to, for example, 100 μm or less by surface treatment such as dry etching using plasma of oxygen, carbon tetrafluoride, and the like, or wet etching using phosphoric acid and the like. With protrusions 6A, the working fluid is refluxed to a vaporizing portion by the capillary phenomenon.

Furthermore, on the entire outer surface of sheet-shaped container 202, sealing layer 213 made of, for example, metal film 211 and resin film 212 is formed. Thus, entire sheet-shaped container 202 having sealed portions 209A, 209B, 210A and 210B of sealing sheets 202A and 202B is covered with sealing layer 213 without having a sealed portion and hermetically sealed.

Although sealing layer 213 may be made of one layer as long as it can hermetically seal the entire sheet-shaped container 202, it is preferable that sealing layer 213 has at least two-layered structure of at least metal film 211 and resin film 212. In particular, it is further desirable that metal film 211 is formed on sheet-shaped container 202. Thus, metal film 211 can improve the hermetic sealing property with respect to the working fluid and the vapor thereof, and at the same time, resin film 212 can prevent the damage of metal film 211 in advance.

Then, as shown in FIG. 14C, for example, one end of sheet-shaped heat pipe 200 functions as vaporizing portion 207 of the working fluid and the other end functions as condensing portion 208.

As sealing sheets 202A and 202B constituting sheet-shaped container 202, a resin material such as polyimide and polyethylene terephthalate is used. As the working fluid, ethanol, water, flon gas, and the like, which have low saturated vapor pressure, are used. As spacer 204 of partition plate 203, a metallic material having flexibility, for example, aluminum, copper, and the like, or resin material such as polyimide, polyethylene terephthalate, and the like, is used.

Metal film 211 forming sealing layer 213 can be formed by using a metallic material having flexibility, for example, aluminum, copper, and the like. Resin film 212 can be formed by using a resin material such as polyimide, polyethylene terephthalate, and the like. They can be formed of the same material as those of partition plate 203 and sheet-shaped container 202.

Note here that vapor flow path 205 may have any depth that is not smaller than the height of the protrusion and it is designed in accordance with the desired cooling performance. For example, when the height of the protrusion is 100 μm, the depth of vapor flow path 205 may be 100 μm or more.

According to the fourth embodiment of the present invention, since the entire outer surface of sheet-shaped container 202 is sealed with sealing layer 203, the sealing performance of the sealed portion of sheet-shaped container 202 can be significantly improved. Furthermore, even when sheet-shaped heat pipe 200 is used in a place moving in a large range while undergoing small bending deformation, for example, an optical pick-up portion of an optical disk device, the sealing performance is not much deteriorated and high reliability can be obtained.

Sealing sheets 202A and 202B of sheet-shaped container 202 and resin film 212 of sealing layer 213 that seals the entire outer surface thereof may be formed of thermosetting resin. Thus, flexibility and heat resistance of sheet-shaped heat pipe 200 are improved, and in sheet-shaped container 202, deterioration of sealing performance due to softening and thermal deformation does not occur. Therefore, sheet-shaped heat pipe 200 can be used in, for example, a portion in which the temperature change is large or a high temperature portion in electronic equipment.

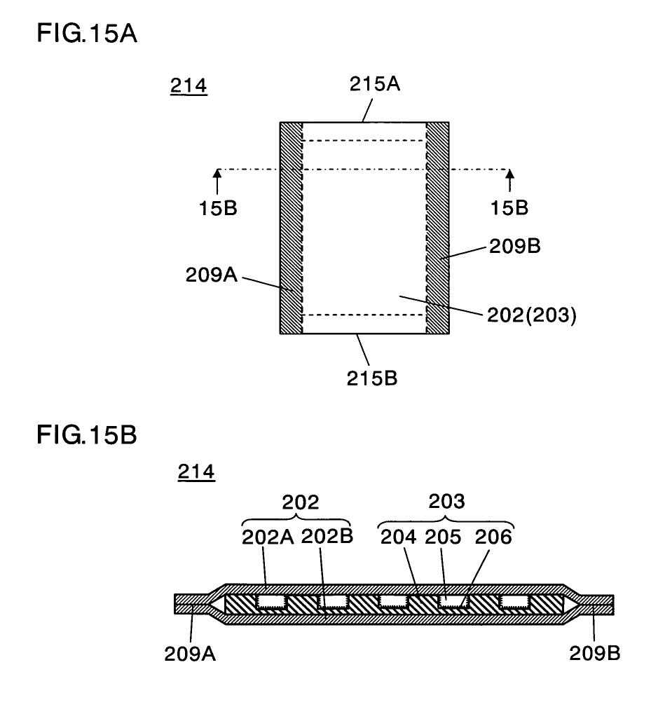

Hereinafter, a method of manufacturing a sheet-shaped heat pipe in accordance with the fourth embodiment of the present invention is described in detail with reference to FIG. 15A to FIG. 18B.

FIG. 15A is a perspective plan view to illustrate a method of manufacturing a container of the sheet-shaped heat pipe in accordance with the fourth embodiment of the present invention. FIG. 15B is a sectional view taken along line 15B-15B of FIG. 15A.

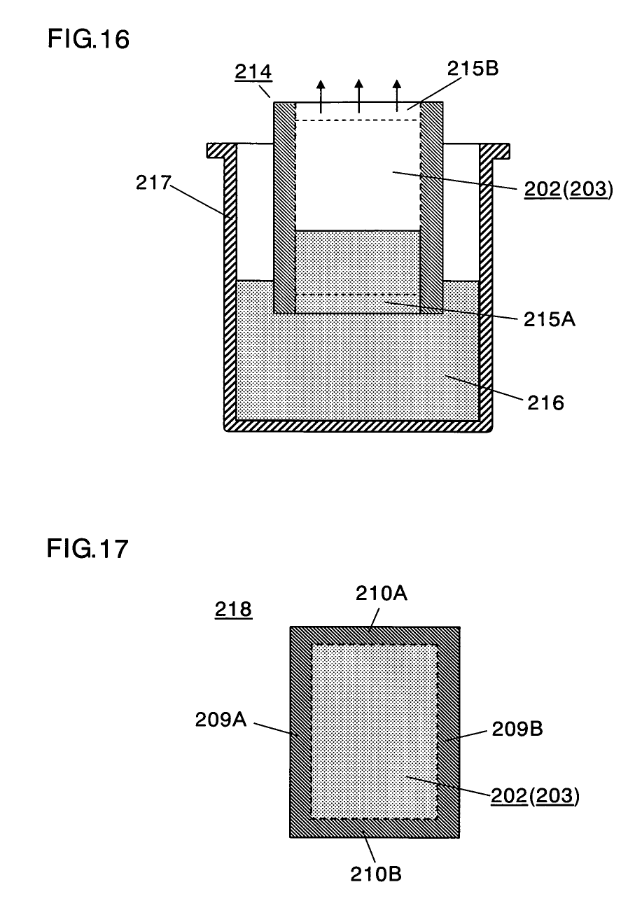

FIG. 16 is a sectional view to illustrate a method of infusing working fluid of the sheet-shaped heat pipe in accordance with the forth embodiment of the present invention.

FIG. 17 is a perspective plan view to illustrate a method of manufacturing a sheet-shaped container of the sheet-shaped heat pipe in accordance with the fourth embodiment of the present invention.

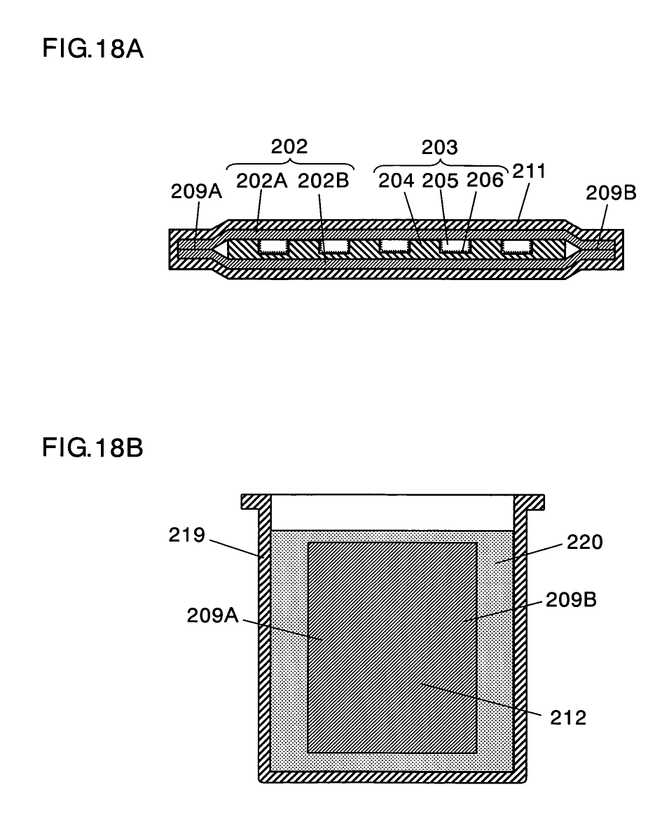

FIG. 18A is a sectional view to illustrate a method of forming a metal film of a sealing layer of the sheet-shaped heat pipe in accordance with the fourth embodiment of the present invention. FIG. 18B is a sectional view to illustrate a method of forming a resin film of a sealing layer.

Firstly, as shown in FIGS. 15A and 15B, sheet-shaped partition plate 203, in which vapor flow paths 205 and fluid flow paths 206 are formed in spacer 204 made of, for example, aluminum and polyimide, is sandwiched between two sealing sheets 202A and 202B made of, for example, polyimide. The outer peripheral portions at both sides in the formation direction of, for example, vapor flow path 205 of two sealing sheets 202A and 202B are bonded by fusing by, for example, heat, ultrasonic wave, and the like. Thereby, sealed portions 209A and 209B (shaded potion in FIG. 15A) are formed. Thus, cylindrical or tubular-shaped container 214 is produced.

Next, as shown in FIG. 16, by dipping, for example, one opening portion 215A of opening portions 215A and 215B of container 214 into working fluid 216 such as ethanol contained in vessel 217, working fluid 216 is infused into fluid flow path 206 of partition plate 203. In this case, working fluid 216 is infused in fluid flow path 206 by the capillary phenomenon. At this time, for example, working fluid 206 may be infused in a state in which the pressure of the other opening portion 215B is reduced. Thus, working fluid 215 can be infused into fluid flow path 206 for a short time.

Thereafter, opening portions 215A and 215B of container 214 are bonded by fusing by, for example, heat, ultrasonic wave.

Then, according to the process mentioned above, as shown in FIG. 17, sheet-shaped container 218, in which the working fluid and the partition plate are hermetically sealed with sealed portions 209A, 209B, 210A and 210B, is produced.

Note here that sheet-shaped container 218 may be produced from container 214 by allowing working fluid to be sucked and infused into the fluid flow path of the partition plate in a reduced pressure atmosphere and by bonding opening portions 215A and 215B.

Next, as shown in FIG. 18A, metal film 211 covering the entire outer surface including sealed portions 209A and 209B and sealed portions 210A and 210B of sheet-shaped container 218 is formed by vapor deposition of, for example, aluminum.

Next, as shown in FIG. 18B, by dipping sheet-shaped container 218 in, for example, liquid polyimide 220 contained in vessel 219 for several tens of seconds, resin film 212 is laminated on metal film 211. Then, resin film 212 is dried and hardened, so that sheet-shaped heat pipe 200 can be obtained, in which sealing layer 213 that forms a laminated structure with sheet-shaped heat pipe 200 is formed on the entire outer surface of container 202.

When sheet-shaped container 218 is dipped into liquid polyimide 220 as mentioned above, ultrasonic wave of about 20 KHz to 100 KHz may be applied. Thus, since resin film 212 having high density and an excellent adhesive property can be formed on metal film 211, hermetic sealing property can be further improved.

According to the fourth embodiment of the present invention, a sheet-shaped heat pipe having an excellent sealing performance such as hermetic sealing can be manufactured efficiently and stably.

It is preferable that since the above-mentioned manufacturing processes can be carried out continuously, a large amount of sheet-shaped heat pipes can be manufactured with high productivity.

### Fifth Embodiment

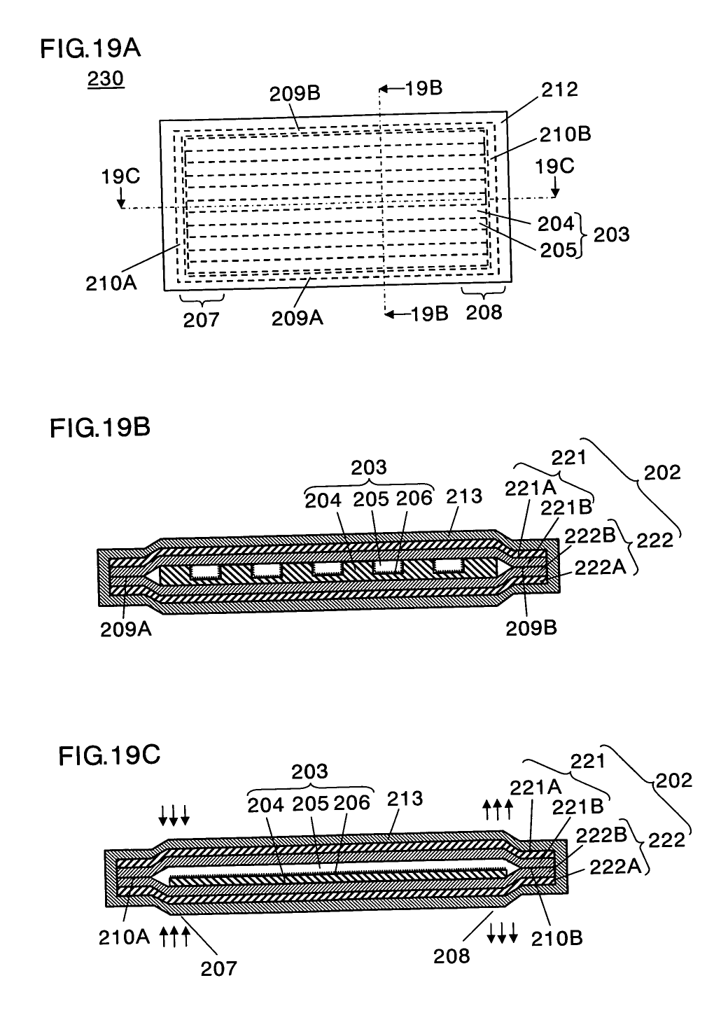

Hereinafter, a sheet-shaped heat pipe in accordance with a fifth embodiment of the present invention is described with reference to FIGS. 19A to 19C.

FIG. 19A is a perspective plan view showing a sheet-shaped heat pipe in accordance with the fifth embodiment of the present invention. FIG. 19B is a sectional view taken along line 19B-19B of FIG. 19A. FIG. 19C is a sectional view taken along line 19C-19C of FIG. 19A. In FIGS. 19A to 19C, the same reference numerals are given to the same configurations as in FIG. 14A to 14C and description therefor is omitted.

The sheet-shaped heat pipe in accordance with the fifth embodiment of the present invention is different from that of the fourth embodiment in that a sheet-shaped container is configured by a laminated film of a metal film and a resin film and that a sealing layer is formed of only a resin layer.

In FIGS. 19A to 19C, sheet-shaped heat pipe 230 in accordance with the fifth embodiment of the present invention includes sheet-shaped container 202 in which two flexible sealing sheets 221 and 222 are bonded at the outer peripheries thereof, and sheet-shaped partition plate 203 made of flexible material together with working fluid (not shown) whose saturated vapor pressure is low encapusulated in container 202.

Then, sealing sheet 221 has a laminated configuration of, for example, metal film 221A and resin film 221B in which resin film 221B is formed on a surface that is brought into contact with partition plate 203. Similarly, sealing sheet 222 also has a laminated configuration of, for example, metal film 222A and resin film 222B in which resin film 222B is formed on a surface that is brought into contact with partition plate 203.

Furthermore, as shown in FIG. 19B, partition plate 203 has spacer 204 including a plurality of vapor flow paths 205 and fluid flow paths 206 provided on the inner surfaces of respective vapor flow paths 205.

Similar to the fourth embodiment of the present invention, as shown in FIG. 2, as fluid flow path 206, minute protrusions 6A are formed on spacer 204 to the thickness of about 100 μm. With protrusions 6A, working fluid is refluxed to a vaporizing portion by the capillary phenomenon.

Furthermore, on the entire surface of sheet-shaped container 202, sealing layer 213 made of a resin film is formed. Thus, entire sheet-shaped container 202 having sealed portions 209A and 209B and sealed portions 210A and 210B of sealing sheets 221 and 222 is covered with sealing layer 213 without having a sealed portion and hermetically sealed.

Then, as shown in FIG. 19C, for example, one end of sheet-shaped heat pipe 230 functions as vaporizing portion 207 of the working fluid and the other end functions as condensing portion 208.

Herein, as sealing sheets 221 and 222 constituting sheet-shaped container 202, a resin material such as polyimide and polyethylene terephthalate is used. Furthermore, as the working fluid, ethanol, water, flon gas, and the like, which have low saturated vapor pressure, are used. As the material of partition plate 203, a flexible metallic material such as aluminum, copper, and the like, or a resin material such as polyimide, polyethylene terephthalate, and the like, can be used.

Furthermore, a resin film forming sealing layer 213 can be formed by using the same material as that of sheet-shaped container 202, for example, a resin material such as polyimide, polyethylene terephthalate, and the like.

According to the fifth embodiment of the present invention, since the entire outer surface of a sheet-shaped container can be sealed with a sealing layer, reliability such as a sealing property of the sealed portion of the sheet-shaped container can be significantly improved.

Furthermore, by configuring the sheet-shaped container in a laminated configuration of a metal film and a resin film, the metal film can be formed on a flat surface, so that the formation becomes easy. In addition, since a sealing layer can be formed of only a resin film, a sheet-shaped heat pipe can be realized with high productivity.

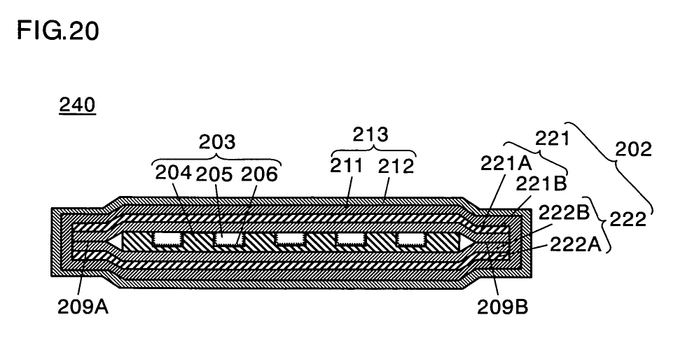

The fifth embodiment describes an example in which sealing layer 213 is configured by one layer of a resin film. However, the configuration is not necessarily limited to this. For example, as shown in a sectional view showing sheet-shaped heat pipe 240 in FIG. 20, sealing layer 213 may have two-layered structure of metal film 211 and resin film 212.

Thus, metal films 221A and 222A constituting sealing sheets 221 and 222 of sheet-shaped container 202 as well as metal film 211 constituting sealing layer 213 can further improve hermetic sealing property with respect to working fluid or the vapor thereof.

Resin film 221B and 222B of sealing sheets 221 and 222 of sheet-shaped container 202 as well as a resin film of sealing layer 213 for sealing the entire outer surface thereof may be formed of thermosetting resin. Thus, since the flexibility and the heat resistance of the sheet-shaped heat pipe are improved, deterioration of sealing performance due to softening or thermal deformation of sheet-shaped container 202 does not occur. Therefore, the sheet-shaped heat pipe can be used in, for example, a portion in which the temperature change is large or a high temperature portion in electronic equipment.

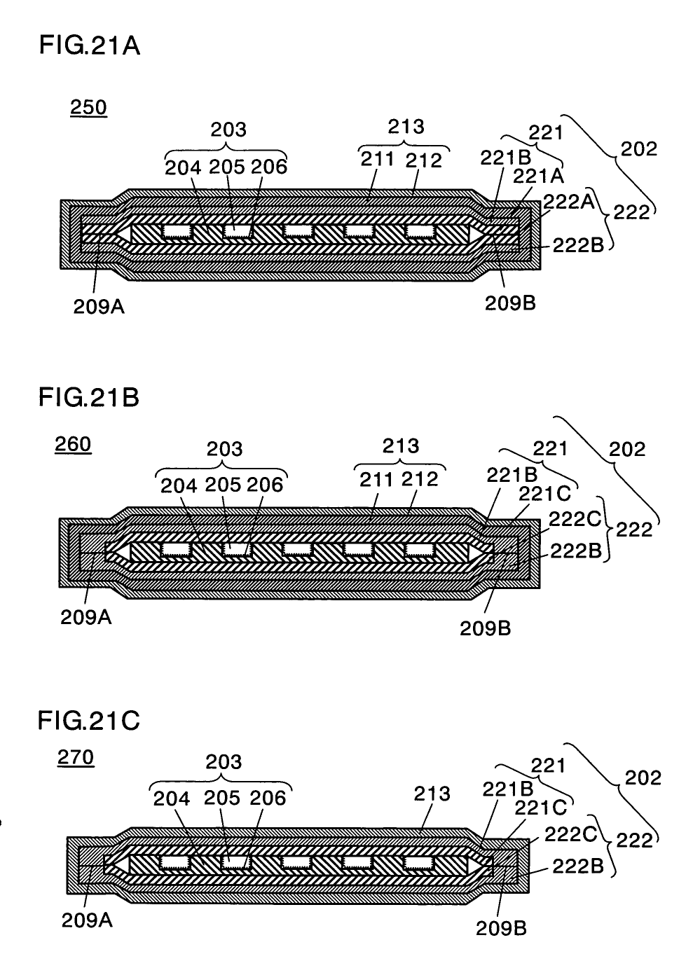

Hereinafter, a modified example of the sheet-shaped heat pipe in accordance with the fifth embodiment of the present invention is described with reference to FIG. 21A to FIG. 21C.

FIG. 21A is a sectional view showing another example 1 of the sheet-shaped heat pipe in accordance with the fifth embodiment of the present invention, and FIG. 21B is a sectional view showing another example 2 of the sheet-shaped heat pipe in accordance with the fifth embodiment of the present invention.

In each of the other examples mentioned above is different from the fifth embodiment in the configuration of the sheet-shaped container including a laminated configuration of a metal film and a resin film.

Firstly, as shown in FIG. 21A, in sheet-shaped heat pipe 250 of another example 1, metal films 221A and 222A constituting sealing sheets 221 and 222 of sheet-shaped container 202 are provided at the side of partition plate 203.

That is to say, since absorption of working fluid by a resin film can be completely prevented by metal films 221A and 222A provided at the side of partition plate 203, it is possible to realize sheet-shaped heat pipe 250 having high reliability in which the reduction of the working fluid is small over a long time.

In this case, since sheet-shaped container 202 is sealed by fusion of metal films 221A and 222A, it is more difficult to secure complete sealing performance as compared with the fusion of resin films 221B and 222B. This is because the melting temperature is generally high in the fusion of metal films 221A and 222B, bubbles etc. easily occur in resin films 221B and 222B when metal films 221A and 222B are fused. Therefore, in sheet-shaped heat pipe 250 in accordance with another example 1, it is preferable that sealing layer 213 is configured by at least a laminated film of metal film 211 and resin film 212 to hermetically seal the entire outer surface of sheet-shaped container 202.

Then, as shown in FIG. 21B, in sheet-shaped heat pipe 260 of another example 2, as compared with another example 1, metal films 221C and 222C of sheet-shaped container 202 are formed at the side of partition plate 203 in a way in which they are smaller than resin films 221B and 222B. Thus, another example 2 avoids the above-mentioned problems occurring when metal films 221C and 222C are fused.

That is to say, since the sealed portion of sheet-shaped container 2 is sealed by fusion of resin films 221B and 222B, the fusion can be carried out at low temperature and fusion interfaces of resin films 221B and 222B are integrated, so that the bonding with excellent sealing performance can be realized. Therefore, in particular, in this case, as sheet-shaped heat pipe 270 shown in another example 3 in FIG. 21C, sealing layer 213 may be formed of only a resin film.

With this configuration, since a sheet-shaped container can be hermetically sealed by fusing resin films, a sheet-shaped heat pipe having excellent sealing performance can be obtained.

### Sixth Embodiment

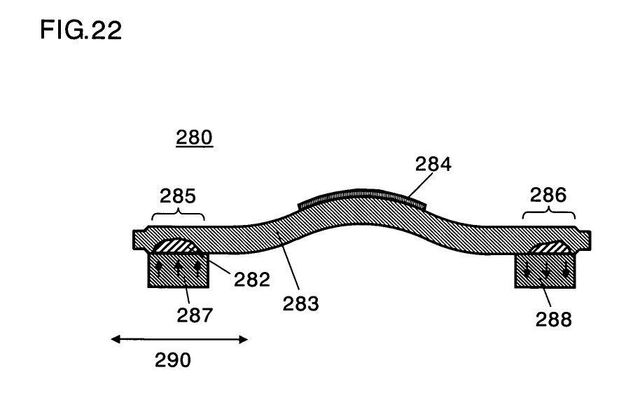

FIG. 22 is a view to illustrate a state in which a sheet-shaped heat pipe in accordance with the sixth embodiment of the present invention is mounted on electronic equipment.

Sheet-shaped heat pipe 280 in accordance with the sixth embodiment of the present invention has reinforcing member 284 on at least a part of the surface of the outer periphery thereof so as to prevent crimp and breakage when the degree of bending of sheet-shaped heat pipe 280 is large.

Furthermore, metal films 282 on the portions that are brought into contact with vaporizing portion 285 and condensing portion 286 on both ends of sheet-shaped heat pipe 280 are exposed from resin film 283 and coupled to heat generating portion 287 and heat dissipating portion 288 of electronic component to be used.

That is to say, FIG. 22 shows a state in which sheet-shaped heat pipe 280 is coupled to heat generating portion 287 reciprocating in the direction, for example, shown by arrow 290 and to fixed heat dissipating portion 288. Then, reinforcing member 284, which is formed as, for example, a thin film, is provided on at least a part of the outer periphery whose degree of bending of sheet-shaped heat pipe 280 is large.

Herein, reinforcing member 284 is formed by vapor deposition or sputtering of a metal thin film such as aluminum, copper, and chromium in accordance with the necessary rigidity. In the above-mentioned example, reinforcing member 284 is a metal thin film, however, it may have a configuration of a laminated film formed by applying polyimide having large modulus of elasticity and then forming a metal thin film. Alternately, it may have a configuration in which a polyimide film or other organic film is fixed via an adhesive layer.

This embodiment describes an example in which metal film 282 of sheet-shaped heat pipe 280 is exposed and coupled to heat generating portion 287 and heat dissipating portion 288 of electronic equipment.

This can improve the heat conductivity between electronic equipment and sheet-shaped heat pipe 280. However, metal film 282 of both vaporizing portion 285 and condensing portion 286 of sheet-shaped heat pipe 280 are not necessarily exposed and coupled. Only one of them may be exposed. Alternatively, metal film 282 may not be exposed.

According to the sixth embodiment, by providing a reinforcing member, even if excessive distortion such as deformation occurs in the sheet-shaped heat pipe, the reinforcing member prevents crimp. Consequently, a sheet-shaped heat pipe that is not easily broken can be obtained.

Furthermore, even when the sheet-shaped heat pipe is mounted on a place that is partially bent with a small bending radius, bending of the inner partition plate at acute angle can be relieved. Thus, the vapor flow path and the fluid flow path of the partition plate can be prevented from being crashed or closed.

Note here that the size, shape and position to be mounted of reinforcing member 284 are determined with respect to shape or portion to be bent of electronic equipment to be used.

Furthermore, providing sheet-shaped reinforcing member 284 on the surface of sheet-shaped heat pipe 280 and carrying out coupling in state metal film 282 is exposed are not necessarily applied simultaneously.

Furthermore, the sheet-shaped heat pipe in accordance with the sixth embodiment of the present invention can be similarly applied to the sheet-shaped heat pipes of the above-mentioned embodiments and the same effect can be obtained.

In each embodiment, as a sealing layer covering the entire outer surface of the sheet-shaped container, the case where one metal layer and one resin layer are used was described. However, the sealing layer is not limited to this configuration. For example, a plurality of laminated films of a metal film and a resin film may be used. Furthermore, when the resin film has low absorption and permeation with respect to working fluid, only a resin film may be used.

Thus, a highly hermetic sealing property can be secured and even in a place with harsh environment, a sheet-shaped heat pipe with high reliability can be realized.

### Seventh Embodiment

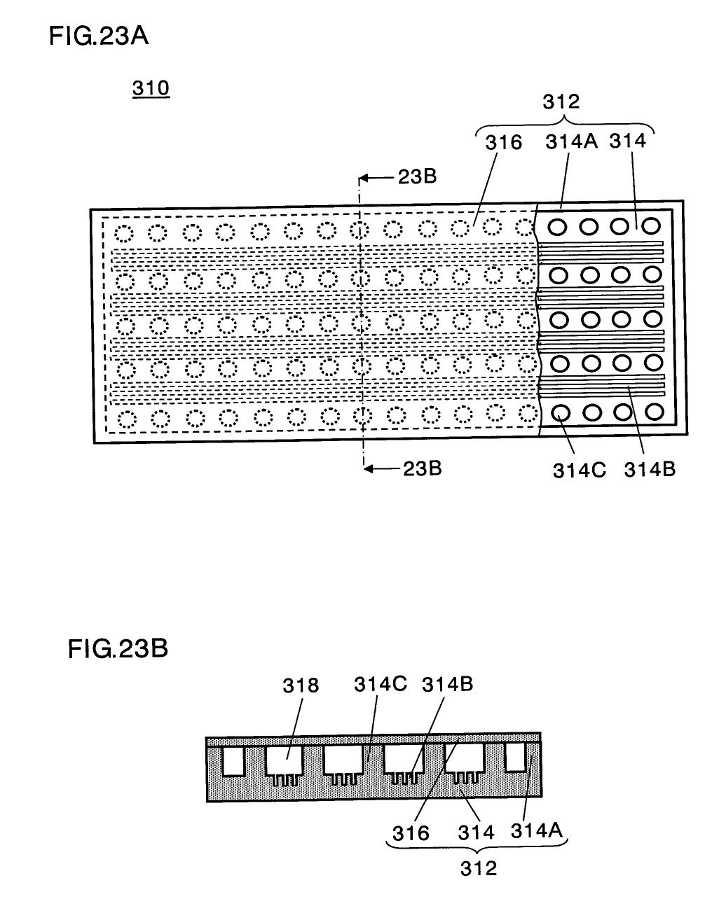

FIG. 23A is a plan view showing a configuration of sheet-shaped heat pipe 310 in accordance with a seventh embodiment of the present invention. FIG. 23B is a sectional view taken along line 23B-23B of FIG. 23A. In FIG. 23A, for easy understanding of the inner structure, upper sheet 316 is shown partially broken away.

Sheet-shaped heat pipe 310 of this embodiment includes sheet-shaped container 312 inside of which is maintained in the reduced pressure state, working fluid (not shown) filled in sheet-shaped container 312, vapor flow paths 318 and fluid flow paths 314B provided inside sheet-shaped container 312, a plurality of supports 314C provided inside sheet-shaped container 312 for preventing vapor flow path 318 from being clogged.

Furthermore, sheet-shaped heat pipe 310 of this embodiment has a rectangular shape in which supports 314C are arranged in an array. Furthermore, fluid flow paths 314B are provided by a plurality of grooves formed between supports 314C along the longitudinal direction of sheet-shaped container 312.

Sheet-shaped container 312 is sealed by bonding outer peripheral frame 314A provided on the outer peripheral region of lower sheet 314 and upper sheet 316. Although not shown, a part of the region is opened because it is necessary that the inside of sheet-shaped container 312 is evacuated and working fluid is then infused after bonding. After these processes are finished, only the opened region is further bonded.

Furthermore, in this embodiment, support 314C and fluid flow path 314B are integrated with lower sheet 314. Therefore, no particular process is carried out with respect to upper sheet 316.

Sheet-shaped container 312 includes lower sheet 314 and upper sheet 316 having a structure in which, for example, a metal thin film is formed on a polyimide resin sheet. In the case of this embodiment, support 314C, fluid flow path 314B and outer peripheral frame 314A are formed on lower sheet 314. These can be formed by, for example, the following method.

A die including a concave shape corresponding to outer peripheral frame 314A and supports 314C of lower sheet 314 and a convex shape corresponding to fluid flow path 314B is prepared. For example, a polyimide resin sheet is inserted into this die. Then, the die is heated and pressed, so that the shape formed on the die is transferred to a resin sheet. Thus, lower sheet 314 on which outer peripheral frame 314A, fluid flow path 314B and support 314C are formed can be formed. This manufacturing method has a feature that lower sheet 314 can be formed only by preparing a die easily and with high productivity. Furthermore, the height of the support can be formed relatively freely in the range of about 50 μm to 2 mm. Furthermore, the groove corresponding to fluid flow path 314B can be formed deeply.

After lower sheet 314 is formed in this way, lower sheet 314 is bonded to upper sheet 316 made of the same polyimide resin at outer peripheral frame 314A. Thus, sheet-shaped container 312 can be formed.

When lower sheet 314 and upper sheet 316 are bonded, a part of outer peripheral frame 314A remains unbonded. Thereafter, the inside is sufficiently evacuated from this region. In this case, since supports 314C are provided, space as vapor flow path 318 is not clogged due to atmospheric pressure. After the inside is sufficiently degassed, working fluid is infused and the part region is sealed. Thus, sheet-shaped heat pipe 310 is produced. As the adhesive for bonding, epoxy adhesive and silicone adhesive can be used. In particular, it is desirable to use adhesive for vacuum. Alternatively, sheet resins or metal thin films laminated on the sheet may be bonded by ultrasonic wave.

For lower sheet 314 and upper sheet 316 of sheet-shaped container 312, when the above-mentioned polyimide resin sheet is used, it is desirable that a metal thin film such as copper or aluminum is formed on the surface thereof. It is preferable that such metal thin films are formed at least inside of sheet-shaped container 312. The metal thin film can be formed by, for example, vacuum vapor deposition. After the metal thin film is formed, a polyimide resin sheet is further attached thereto, so that a laminated configuration may be formed. Alternatively, a laminated configuration may be formed by applying liquid polyimide resin on a metal thin film. Furthermore, a sheet having a configuration in which a polyimide resin sheet and a metal foil are attached to each other may be used. Furthermore, a resin sheet is not limited to a polyimide resin sheet. Any sheets can be similarly employed as long as they have heat resistance to about 150° C. or more and have bending property such that they can be formed into a sheet.

It is desirable that the thickness of this sheet-shaped container 312 is set as mentioned below. That it to say, from the viewpoint of manufacture and securing flexibility, it is desirable that the thickness of vapor flow path 318 is about 0.1 mm to 1 mm and the depth of the groove of fluid flow path 314B is about 0.05 mm to 0.5 mm. Furthermore, it is desirable that the thickness of the sheet itself is about 0.02 mm to 0.3 mm. Taken this into consideration, the thickness of sheet-shaped heat pipe 310 of this embodiment can be about 0.2 mm to 2 mm. However, since sheet-shaped container 312 has a thickness of about 0.1 mm to 1 mm in almost all the region and respective supports 314C are formed individually, sheet-shaped container 312 can be bent sufficiently. Thus, it can be attached to three-dimensional shaped heat generating portion, enabling efficient cooling.

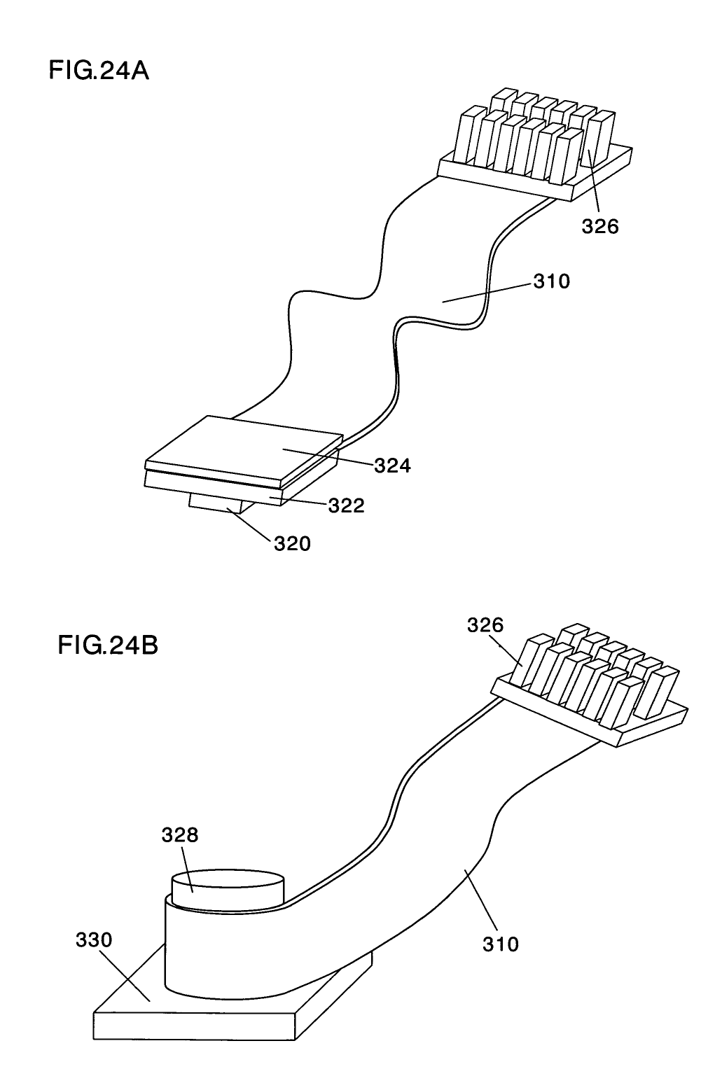

FIGS. 24A and 24B are schematic views showing an outline to illustrate a configuration for cooling a heat generation portion of electronic equipment by using sheet-shaped heat pipe 310 in accordance with this embodiment.

FIG. 24A shows a configuration in which one end of sheet-shaped heat pipe 310 is brought into close contact with heat dissipating plate 322 provided with semiconductor laser 320 by using pressing plate 324, and the other end is brought into close contact with heat dissipating fin 326.

In the above-mentioned configuration, since heat dissipating fins 326 are fixed to a case (not shown) and sheet-shaped heat pipe 310 has flexibility, even when semiconductor laser 320 moves, the movement is not prevented and excellent heat dissipation can be carried out.

Similarly, FIG. 24B shows a configuration in which one end of sheet-shaped heat pipe 310 is wound to cylindrical heat generating portion 328 of electronic equipment and adhesively bonded thereto with, for example, adhesive having an excellent thermal conductivity, and the other end is brought into close contact with heat dissipating fin 326. Note here that heat generating portion 328 is a CPU attached to, for example, circuit board 330. In this way, even when heat generating portion 328 has a three-dimensional form, since sheet-shaped heat pipe 310 can be brought into close contact with the surface of the heat generating region, as compared with a conventional heat pipe, an excellent heat dissipation property can be realized.

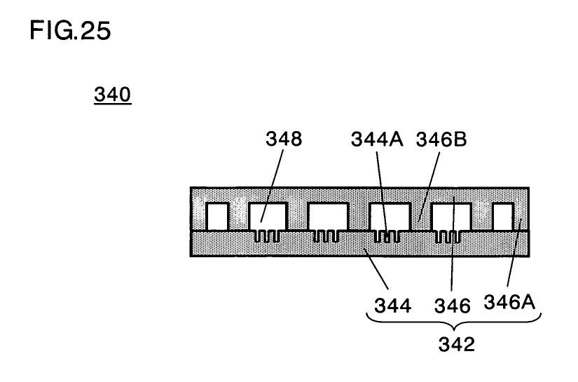

Hereinafter, another example of the sheet-shaped heat pipe in accordance with the seventh embodiment of the present invention is described with reference to FIG. 25 to FIG. 27.

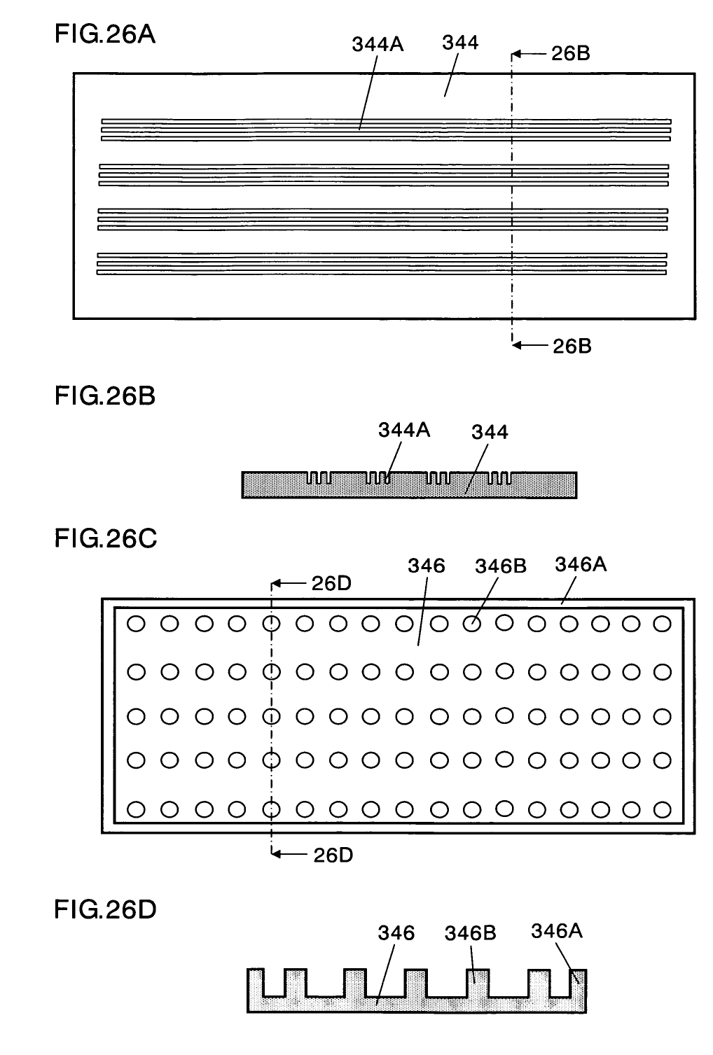

FIG. 25 is a sectional view showing the short-side direction of another example 1 of the sheet-shaped heat pipe in accordance with the seventh embodiment of the present invention. FIG. 26A is a plan view showing lower sheet 344 of sheet-shaped container 342 constituting sheet-shaped heat pipe 340, FIG. 26B is a sectional view taken along line 26B-26B of FIG. 26A, FIG. 26C is a plan view showing upper sheet 346 of sheet-shaped container 342 constituting sheet-shaped heat pipe 340, and FIG. 26D is a sectional view taken along line 26D-26D of FIG. 26C.

The planar shape of sheet-shaped heat pipe 340 is the same as that of sheet-shaped heat pipe 310 of this embodiment but it is different in that fluid flow paths 344A is formed on lower sheet 344 and supports 346B and outer peripheral frame 346A are formed on upper sheet 346.

For lower sheet 344, same as in the manufacturing method mentioned above, for example, a polyimide resin sheet is used and a groove is formed by using a die and thus fluid flow path 344A can be made.

Furthermore, similarly, as to upper sheet 346, support 346B and outer peripheral frame 346A having a predetermined height can be used by using a die. In this case, as a die for forming lower sheet 344, a die provided with concave and convex portions corresponding to fluid flow path 344A is used. As a die for forming upper sheet 346, a die provided with concave portions corresponding to outer peripheral frame 346A and support 346B is used.

Lower sheet 344 having fluid flow paths 344A and upper sheet 346 having supports 346B and outer peripheral frame 346A are bonded to each other with a part of upper sheet 346A unbonded, and further the inside is sufficiently evacuated from the unbonded region. In this case, since supports 346B are formed, space corresponding to vapor flow path 348 is not clogged due to atmospheric pressure. After the inside is sufficiently degassed, working fluid is infused therein and the part region is sealed. Thus, sheet-shaped heat pipe 340 in accordance with another example 1 is produced.

Note here that lower sheet 344 and upper sheet 346 of sheet-shaped container 342 can be made of the same material as that of sheet-shaped container 312 of this embodiment. Furthermore, the shape of produced sheet-shaped heat pipe 340 is the same as that of sheet-shaped heat pipe 310 of this embodiment. However, in the case of sheet-shaped heat pipe 340 of example 1, lower sheet 344 is provided with only fluid flow path 344A and upper sheet 346 is provided with support 346B and outer peripheral frame 346A.

Lower sheet 344 and upper sheet 346 can be formed by the above-mentioned manufacturing method, respectively. Furthermore, in particular, fluid flow path 344A of lower sheet 344 can also be formed by mechanical process using a dicing saw.

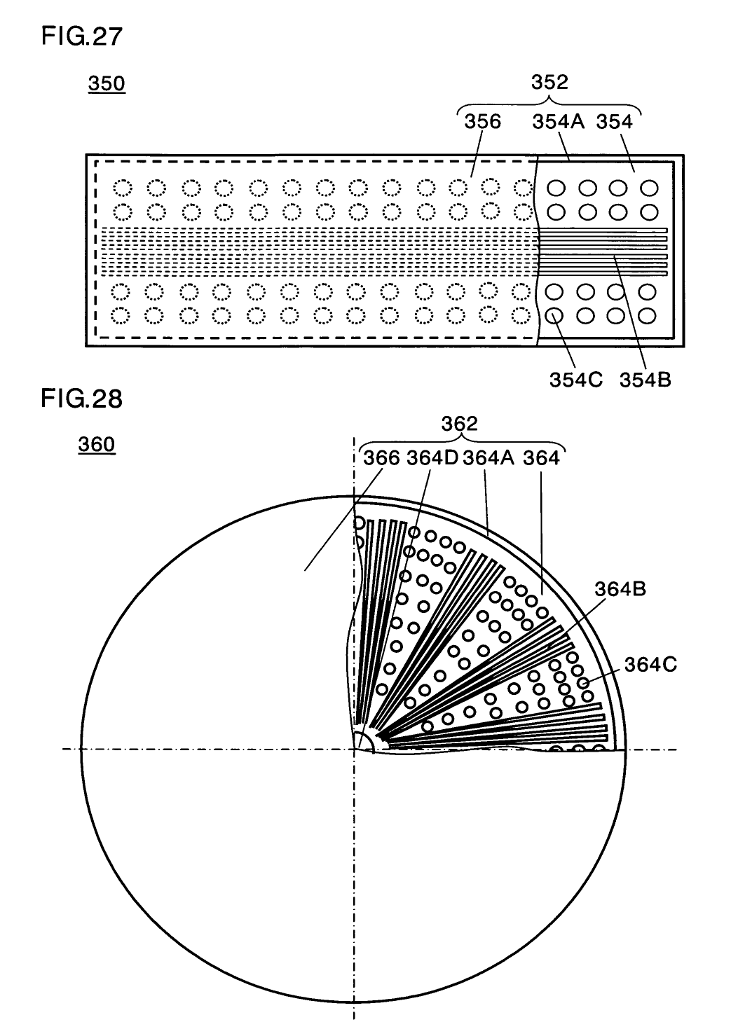

Furthermore, FIG. 27 is a plan view to illustrate a configuration of another example 2 of the sheet-shaped heat pipe in accordance with the seventh embodiment of the present invention. In FIG. 27, for easy understanding of the inner structure, upper sheet 356 is shown partially broken away. Sheet-shaped heat pipe 350 is different from sheet-shaped heat pipe 310 of this embodiment in that in sheet-shaped heat 350, fluid flow path 354B is disposed in the center region and a vapor flow path is disposed on the outer periphery.

In sheet-shaped container 352, lower sheet 354 and upper sheet 356 are bonded at outer peripheral frame 354A provided on lower sheet 354 so as to be sealed and integrated. Furthermore, lower sheet 354 is provided with outer peripheral frame 354A, fluid flow path 354B and support 354C. The manufacturing method and materials thereof are made to be the same as those of sheet-shaped heat pipe 310 of this embodiment, and the description therefor is omitted.

Note here that in this embodiment, a method of manufacturing the lower sheet and the upper sheet of the sheet-shaped container by using a die was described. However, the present invention is not necessarily limited to this. For example, the following method may be employed.

First of all, a manufacturing method using an etching method is described.

Firstly, a resin sheet including the thicknesses of the support and outer peripheral frame is prepared. To one principal surface of this sheet, a photoresist film is applied and then exposed by using a mask having array-shaped dot patterns, so that the photoresist film is left on the surface corresponding to places to be formed into supports.

Next, the resin sheet is processed to a predetermined depth with a region on which the photoresist film was applied left by carrying out dry etching, wet etching or dry and wet etching, or sandblasting. It is preferable that the processing depth is in the range from about 50 μm to 500 μm.

Next, after the photoresist film is removed, a photoresist film is further applied on the entire surface, and then exposed by using a mask for forming a fluid flow path, followed by developing process. Thereafter, when dry etching is carried out, a groove with a predetermined depth is formed. This groove may be used as a fluid flow path. In this case, when not only the shape of the groove but also the conditions of dry etching are appropriately set, on the surface of the resin sheet including the groove, for example, a large number of minute needle protrusions shown in FIG. 2 can be formed. It is preferable that such needle-like protrusions are provided because the capillary phenomenon can be easily caused. Furthermore, the surface thereof may be processed to have a hydrophilic property. By carrying out the process to have a hydrophilic property, the capillary phenomenon can be generated more remarkably.

Next, as alternate method, mechanical processing method may be employed. That is to say, the surface of a resin sheet may be mechanically processed so as to form grooves corresponding to supports and fluid flow paths. Firstly, the resin sheet is ground in both the longitudinal direction of the resin sheet and the short-side direction perpendicular to the longitudinal direction. In this case, outer peripheral region is not ground. With such a grinding, supports and an outer peripheral frame whose cross-section is a square shape or rectangular shape are formed. Thereafter, when grooves corresponding to fluid flow paths are ground along the longitudinal direction of the resin sheet, a lower sheet having an outer peripheral frame, fluid flow paths and supports can be formed. Note here that the grooves corresponding to the fluid flow paths can be easily formed in the width of about 20 μm to 100 μm and the depth of about 100 μm by carrying out grinding with the use of a dicing saw. In addition, the surface of the groove may be processed to have a hydrophilic property. Note here that on the lower sheet, only the fluid flow path may be formed by grinding, and on the upper sheet, the outer peripheral frame and the supports may be formed by grinding.

In the seventh embodiment of the present invention, a container configured by an upper sheet and a lower sheet is described as an example. However, the configuration is not necessarily limited to this. For example, the container may be used as a sheet-shaped partition plate in accordance with each of the above-mentioned first to sixth embodiments. In this case, it is preferable that an opening portion is provided on at least the outer peripheral frame in the longitudinal direction. However, when the partition plate itself is used as a container, it may be a sealed structure.

Thus, a sheet-shaped heat pipe having a highly hermetic sealing property and high reliability can be realized even when it is used in a place in the harsh environmental condition.

### Eighth Embodiment

FIG. 28 is a plan view showing a configuration of sheet-shaped heat pipe 360 in accordance with an eighth embodiment of the present invention. In FIG. 28, for easy understanding of the inner structure, upper sheet 366 is shown partially broken away.

Sheet-shaped heat pipe 360 in accordance with this embodiment includes sheet-shaped container 362 inside of which is maintained in a reduced pressure state, working fluid (not shown) filled in sheet-shaped container 362, a vapor flow path and fluid flow path 364B for the working fluid, which are provided inside sheet-shaped container 362, and a plurality of supports 364C provided inside sheet-shaped container 362 for preventing clogging of the vapor flow path. Furthermore, sheet-shaped container 362 has a circular shape and the above-mentioned supports 364C are arrayed from the center of the circle toward the outer peripheral region. Then, fluid flow paths 364B are formed by a plurality of grooves formed from the central region of the circle toward the outer peripheral region.

Furthermore, sheet-shaped container 362 includes lower sheet 364 and upper sheet 366. Then, outer peripheral frame 364A and inner peripheral frame 364D of lower sheet 364 are adhesively bonded to and integrated with the corresponding portions of upper sheet 366 with, for example, adhesives.

Also in sheet-shaped heat pipe 360 of this embodiment, similar to sheet-shaped heat pipe 310 in accordance with the seventh embodiment, lower sheet 364 is provided with outer peripheral frame 364A, fluid flow path 364B, support 364C and inner peripheral frame 364D.

In other words, sheet-shaped heat pipe 360 and sheet-shaped heat pipe 310 of the seventh embodiment have substantially the same configuration and can be produced by using similar materials and producing method except that sheet-shaped heat pipe 360 of this embodiment has a circular shape and is provided with not only outer peripheral frame 364A but also inner peripheral frame 364D.

Fluid flow path 364B is formed in a way in which the width is increased from the center of the circle toward the outer periphery. Furthermore, a place between fluid flow path 364B and upper sheet 366 and a place between a region excluding support 364C and upper sheet 366 become vapor flow path.

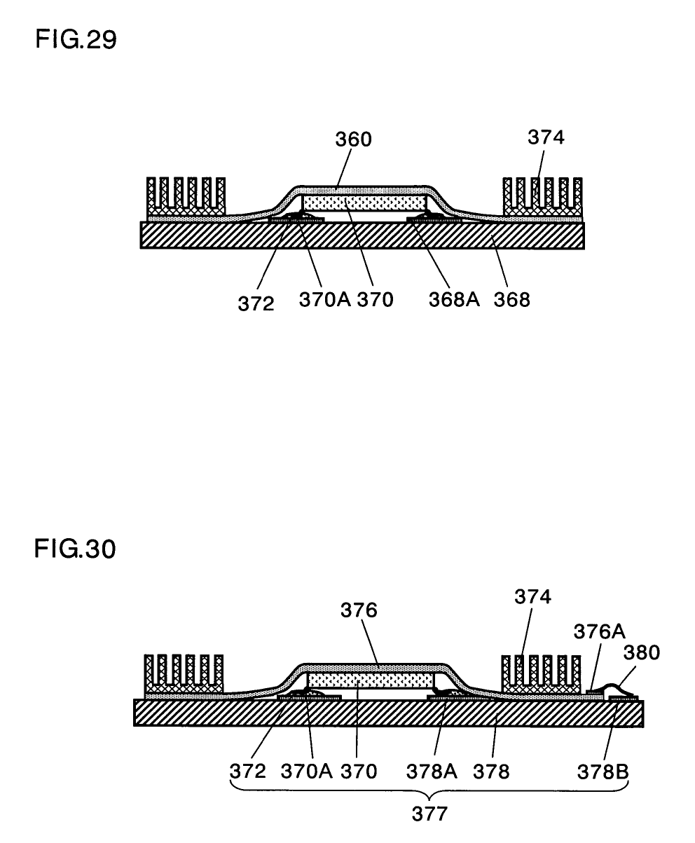

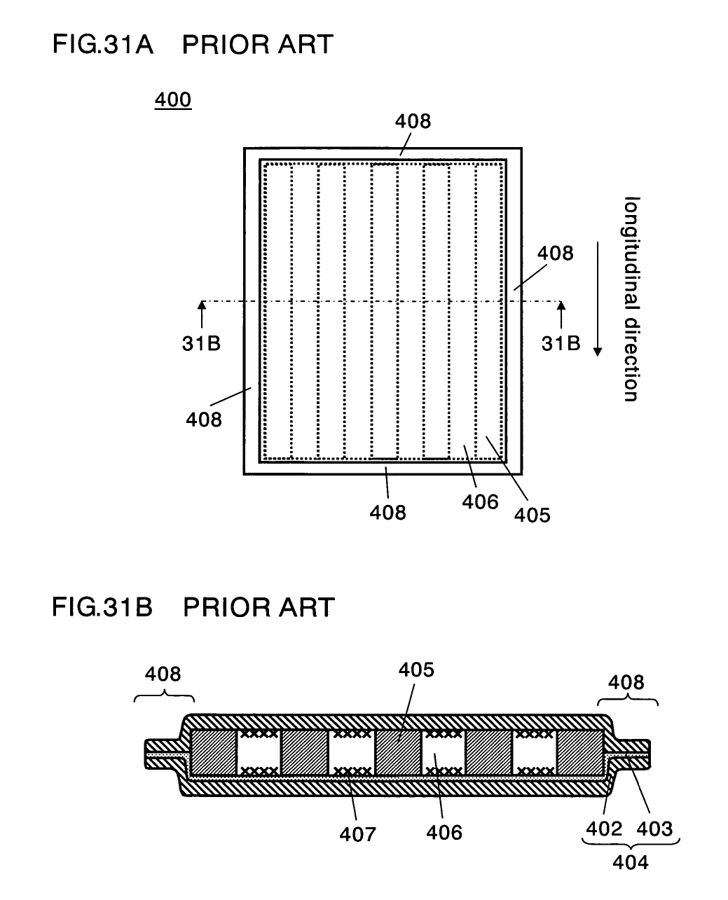

In this embodiment, since sheet-shaped heat pipe 360 has a circular shape, cooling configuration as shown in FIG. 29 can be obtained. FIG. 29 is a sectional view to illustrate a configuration for cooling heat generating portion 370, for example, a CPU mounted on the surface of circuit board 368 built in electronic equipment.

Terminal pin 370A of heat generating portion 370 (hereinafter, referred to as “CPU”) is packaged on electrode terminal 368A of circuit board 368 with solder 372. Accordingly, since CPU 370 is not brought into direct contact with circuit board 368, heat generated from CPU 370 is required to be dissipated efficiently. In such a case, when sheet-shaped heat pipe 360 of this embodiment is used, cooling can be carried out with a small area efficiently.

The center of sheet-shaped heat pipe 360 of this embodiment is adhesively bonded to CPU 370 with an adhesive agent having an excellent thermal conductivity. Then, along the outer peripheral region of sheet-shaped heat pipe 360, circular heat dissipating fin 374 is provided. Thus, heat generated at CPU 370 is transferred to the center of sheet-shaped heat pipe 360 and the working fluid becomes vapor, passes through the vapor flow path and moves to the outer periphery. In the outer periphery, the vapor is cooled by heat dissipating fin 374 so as to become working fluid again. This working fluid is transferred through fluid flow path 364B and returns to the center. With this repetition, heat is transferred from the center toward the outer periphery, and can be dissipated to the outside from heat dissipating fin 374.

Sheet-shaped heat pipe 360 has flexibility because the resin of lower sheet 364 and upper sheet 366 of sheet-shaped container 362 is thin. Consequently, sheet-shaped heat pipe 360 can be brought into close contact with CPU 370 easily. Furthermore, even when it is bent, since support 364C is provided, the vapor flow path is not clogged and the property as a heat pipe is not deteriorated.

Note here that in this embodiment, lower sheet 364 is provided with outer peripheral frame 364A, fluid flow path 364B, support 364C and inner peripheral frame 364D, and upper sheet 366 has a simple circular shaped sheet. However, the configuration is not necessarily limited to this. For example, a fluid flow path may be formed on lower sheet 364, and an outer peripheral frame, a support and an inner peripheral frame may be formed on upper sheet 366.

Furthermore, the shape is not limited to circle and may be polygonal shape such as pentagon, hexagon, and octagon, and the like. Furthermore, the fluid flow paths and the supports are not necessarily formed in a radial shape and may be, for example, a helical shape.

Hereinafter, a cooling structure of electronic equipment configured by using another example of the sheet-shaped heat pipe in accordance with the eighth embodiment of the present invention is described.

FIG. 30 is a sectional view showing a configuration for a cooling structure of element equipment configured by using sheet-shaped heat pipe 376 in accordance with another example of the present invention.

As shown in FIG. 30, the cooling structure of electronic equipment includes electronic equipment 377 having heat generating portion 370 and heat transfer means, which is in close contact with heat generating portion 370, for transferring the heat generated in heat generating portion 370 to a heat dissipating region. Then, this heat transfer means is the above-mentioned sheet shaped heat pipe 376. Inside the sheet shaped container, a conductive film (not shown) is formed over the entire surface and a part of this conductive film is exposed so as to provide electrode terminal 376A. Furthermore, electrode terminal 376A of the sheet-shaped container is coupled to ground terminal 378B of electronic equipment 377.

That is to say, electronic equipment 377 includes heat generating portion 370, for example, a CPU packaged on circuit board 378. Heat generating portion 370 (hereinafter, referred to as “CPU”) has terminal pin 370A packaged on electrode terminal 378A of circuit board 378 with solder 372. Therefore, since CPU 370 is not brought into direct contact with circuit board 378, heat generated from CPU 370 is required to be dissipated efficiently. On the contrary, since sheet-shaped heat pipe 376 has flexibility, the central region can be brought into close contact with CPU 370. Thus, heat generated at CPU 370 can be efficiently dissipated to the outside through heat dissipating fin 374 provided on the outer peripheral region. Furthermore, electrode terminal 376A of a conductive film of sheet-shaped heat pipe 376 and grand terminal 378B of circuit board 378 are coupled to each other by, for example, wire lead 380. Thus, CPU 370 and electronic component such as a semiconductor element in the vicinity of CPU 370 can be shielded from electromagnetic noise.

As mentioned above, in the sheet-shaped heat pipe of the present invention, since a sheet with relatively wide area can be obtained, in addition to the heat pipe function, an electromagnetic shielding function can be also added.

1. A sheet-shaped heat pipe comprising:
working fluid;
a partition plate having a vapor flow path which is formed by a concave portion provided in a spacer and through which vapor of the working fluid passes and a fluid flow path which is provided on an inner surface of the concave portion and through which the working fluid passes;
a container with an opening portion, including the working fluid and the partition plate inside thereof; and
a sealed portion for hermetically sealing the opening portion of the container.

2. The sheet-shaped heat pipe of claim 1, wherein
the partition plate has a sheet shape or a cylindrical shape.

3. The sheet-shaped heat pipe of claim 2, wherein
the vapor flow path is formed on an inner peripheral surface of the cylindrical-shaped partition plate.

4. The sheet-shaped heat pipe of claim 1, wherein
the container comprises at least two sealing sheets or a cylindrical sealing film.

5. The sheet-shaped heat pipe of claim 1, wherein
at least the sealed portion of the container further comprises a sealing layer for hermetic sealing.

6. The sheet-shaped heat pipe of claim 4, wherein
the sealing sheet, the sealing film or the sealing layer comprise at least two layers including a metal film and a resin film.

7. The sheet-shaped heat pipe of claim 6, wherein
the metal film is provided at the side of the partition plate.

8. The sheet-shaped heat pipe of claim 6, wherein
in the sealed portion, the metal film is larger than the partition plate and smaller than the resin film.

9. The sheet-shaped heat pipe of claim 1, wherein
a sheet-shaped reinforcing member is provided on an outer surface of the sheet-shaped heat pipe.

10. A method of manufacturing a sheet-shaped heat pipe, the method comprising:
forming a cylindrical container with an opening portion, in which at least a metal film and a resin film are laminated;
encapsulating a partition plate in which a vapor flow path and a fluid flow path are integrated with a spacer in the container;
infusing working fluid from the opening portion of the container; and
forming a sealed portion by bonding the opening portion of the container.

11. The method of claim 1O, wherein
the partition plate has a sheet shape or a cylindrical shape.

12. The method of claim 10, further comprising:
forming a sealing layer for covering at least the sealed portion of the container.

13. A sheet-shaped heat pipe comprising:
a sheet-shaped container having flexibility, inside of which is maintained in a reduced pressure state;
working fluid filled in the container;
a vapor flow path and a fluid flow path of the working fluid, which are provided inside the container; and
a plurality of supports provided inside the container for preventing the vapor flow path from being clogged.

14. The sheet-shaped heat pipe of claim 13, wherein
the container has a rectangular shape, the supports are arranged in an array, the fluid flow path is formed between the supports along the longitudinal direction of the container.

15. The sheet-shaped heat pipe of claim 13, wherein
the container has a shape of circle or polygon, the supports are arranged from a center portion toward an outer peripheral region of the circle or the polygon, and the fluid flow path is formed between the supports from the center portion toward the outer peripheral region of the circle or the polygon.

16. The sheet-shaped heat pipe of claim 13, wherein
the container has a configuration in which outer peripheries of two sheets are bonded to each other.

17. The sheet-shaped heat pipe of claim 16, wherein
the supports are integrated on any one of the two sheets.

18. The sheet-shaped heat pipe of claim 16, wherein
the support and the fluid flow path are formed on different sheets, respectively.

19. The sheet-shaped heat pipe of claim 13, wherein
a conductive film is formed inside the container and a part of the conductive film is exposed so as to provide an electrode terminal.

20. A cooling structure for electronic equipment, comprising:
electronic equipment having a heat generating portion; and
a heat transfer means, which is brought into close contact with the heat generating portion, for transferring heat generated at the heat generating portion to a heat dissipating region;
wherein the heat transfer means is a sheet-shaped heat pipe of claim 19 and the electrode terminal of the conductive film is coupled to a ground terminal of the electronic equipment.

21. The sheet-shaped heat pipe of claim 5, wherein
the sealing sheet, the sealing film or the sealing layer comprise at least two layers including a metal film and a resin film.
